(19) United States
(12) Patent Application Publication
(10) Pub. No.: US 2024/0363783 A1
(43) Pub. Date: Oct. 31, 2024

(54) FLEXIBLE SPACE SOLAR SHEETS AND METHODS FOR THEIR MANUFACTURE AND USE

(71) Applicant: Microlink Devices, Inc., Niles, IL (US)

(72) Inventors: Christopher Youtsey, Libertyville, IL (US); Ian Witting, Wilmette, IL (US)

(21) Appl. No.: 18/644,708

(22) Filed: Apr. 24, 2024

Related U.S. Application Data
(60) Provisional application No. 63/461,791, filed on Apr. 25, 2023.

(51) Int. Cl. H01L 31/054; H01L 31/0392; H01L 31/0445; H01L 31/18

(52) U.S. Cl. CPC H01L 31/0547; H01L 31/03926; H01L 31/0445; H01L 31/0549; H01L 31/18

(57) ABSTRACT

Systems and methods are presented including solar cells or solar sheets having textured coversheets that provide increased light collection efficiency. Some embodiments include a textured solar coversheet configured for installation on a surface of a space-based vehicle or on a surface of a component of a space-based vehicle. The textured solar sheet includes a plurality of solar cells, a polymer coversheet to which the plurality of solar cells are attached, and an ultraviolet rejection film disposed over the polymer coversheet.

### RELATED APPLICATION

The present invention claims benefit of priority to Provisional Patent Application Ser. No. 63/461,791, filed on Apr. 25, 2023 and is incorporated herein by reference in its entirety.

### STATEMENT OF GOVERNMENT INTEREST

This invention was made with government support under Contract No. 80NSSC210479 awarded by the National Aeronautics and Space Administration (NASA). The government has certain rights in this invention.

### BACKGROUND

Space-based vehicles or satellites, such as positioned in a low-Earth orbit (LEO), often rely on solar cells for power. Components on space vehicles have additional requirements compared to terrestrial applications to ensure reliability and protection against the harsh space environment, including resistance to electron and proton radiation, ultraviolet radiation, and atomic oxygen.

### SUMMARY

A solar sheet configured for space-based applications is provided herein. The solar sheet includes a plurality of thin film solar cells. The solar sheet also includes a flexible polymer sheet overlying a light-receiving surface of the plurality of thin film solar cells. A bottom surface of the flexible polymer sheet faces the plurality of thin film solar cells. A top surface of the flexible polymer sheet has texturing operative to recapture light that is initially reflected from the top surface of the flexible polymer sheet. The solar sheet also includes an ultraviolet rejection film disposed over the flexible polymer sheet to protect the solar sheet from light degradation and chemical degradation.

A method of manufacturing a thin film solar sheet for space applications is provided. The method includes aligning a plurality of solar cells with interconnects on a flexible backing layer. The method also includes attaching a back electrode connected to the plurality of solar cells to the flexible backing layer using an adhesive. The method also includes disposing a textured coversheet over the plurality of solar cells and the interconnects. The method also includes forming an ultraviolet rejection film on the textured coversheet to protect the textured coversheet from light degradation and chemical degradation.

A device to enhance light collection efficiency of a plurality of thin film solar cells is provided herein. The device includes a flexible polymer sheet including a textured top surface and a bottom surface. The textured top surface includes a plurality of prismatic structures formed therein. The plurality of prismatic structures is operative to recapture light that is initially reflected from the textured top surface of the flexible polymer sheet. The bottom surface of the flexible polymer sheet is configured to overlay the plurality of thin film solar cells. The device also includes an ultraviolet rejection film disposed over the flexible polymer sheet to protect the solar sheet from light degradation and chemical degradation.

A space-based vehicle is provided herein. The space-based vehicle includes a solar sheet installed on a surface of the space-based vehicle or on a surface of a component of the space-based vehicle. The solar sheet includes a plurality of thin-film solar cells. The solar sheet includes a flexible polymer sheet overlaying and encapsulating a light receiving surface of the plurality of thin film solar cells. A bottom surface of the flexible polymer sheet faces the plurality of thin film solar cells. A top surface of the flexible polymer sheet has texturing operative to recapture light that is initially reflected from the top surface of the flexible polymer sheet. The solar sheet also includes an ultraviolet rejection film disposed over the flexible polymer sheet to protect the solar sheet from light degradation and chemical degradation. The space-based vehicle also includes a power conditioning system configured to operate the plurality of thin film solar cells within a desired power range and configured to provide power in the form of a voltage compatible with an electrical system of the space-based vehicle.

A method of manufacturing a coversheet for a plurality of solar cells for space applications is provided. The method includes receiving a textured coversheet having a size configured to overlay the plurality of solar cells. The method also includes forming an ultraviolet rejection film on the textured coversheet to protect the textured coversheet from light degradation and chemical degradation.

A method of protecting a plurality of solar cells configured for deployment in space is provided. The method includes receiving a flexible polymer coversheet including a textured top surface and a bottom surface. The textured top surface includes a plurality of prismatic structures formed therein. The plurality of prismatic structures is operative to recapture light that is initially reflected from the textured top surface of the flexible polymer coversheet. The bottom surface is configured to overlay the plurality of thin film solar cells. The flexible polymer coversheet includes an ultraviolet rejection film on the textured coversheet to protect the textured coversheet from light degradation and chemical degradation. The method also includes disposing the flexible polymer coversheet over the plurality of solar cells.

### BRIEF DESCRIPTION OF THE DRAWINGS

The foregoing and other objects, features and advantages of the invention will be apparent from the following description, and from the accompanying drawings, in which like reference characters refer to the same parts throughout the different views. The drawings illustrate principles of the invention and are not to scale.

FIG. 1 illustrates a cross-sectional schematic view of a thin-film solar sheet with enhanced light collection efficiency in accordance with various embodiments taught herein.

FIG. 2 illustrates a rendered perspective view of another embodiment of a thin-film solar sheet in accordance with various embodiments taught herein.

FIG. 3 illustrates a cross-sectional view of two neighboring solar cells in the solar sheet according to various embodiments taught herein.

FIG. 4 illustrates a comparison of the measured surface reflectivity as a function of wavelength of light from a solar sheet including a textured coversheet with prismatic structures and a conventional solar sheet with a planar coversheet.

FIGS. 5A and 5B show top views of a conventional solar sheet with a planar coversheet formed of silicone with an ultraviolet rejection (UVR) coating.

FIGS. 6A and 6B show top views of the solar sheet with textured coversheet as taught herein with a UVR coating.

FIGS. 7A and 7B show top views of the solar sheet with textured coversheet as taught herein.

FIG. 8 is an image of a solar sheet with a planar coversheet illustrating the poor surface quality.

FIGS. 9 and 10 illustrate solar sheets with a textured coversheet having prismatic structures as taught herein.

FIG. 11A illustrates current-voltage (I-V) curves for a conventional solar sheet with planar coversheet at three stages of manufacture.

FIG. 11B is a table of relevant parameters for the solar sheet in FIG. 11A.

FIG. 12A illustrates I-V curves for a solar sheet with textured coversheet including prismatic structures at three stages of assembly according to some embodiments taught herein.

FIG. 12B is a table of relevant parameters for the solar sheet in FIG. 12A.

FIG. 13A illustrates I-V curves for a solar sheet with textured coversheet including prismatic structures at three stages of assembly according to some embodiments taught herein.

FIG. 13B is a table of relevant parameters for the solar sheet in FIG. 13A.

FIG. 14 illustrates an embodiment of a coversheet design including linear prismatic structures according to various embodiments of the present disclosure.

FIGS. 15A-15B illustrate scanning electron microscope (SEM) images at different magnification factors of a fluorinated ethylene propylene coversheet including a plurality of prismatic structures produced by embossing according to various embodiments taught herein.

FIG. 16 illustrates transmissivity as a function of wavelength of light as measured for several materials.

FIG. 17 illustrates a scanning laser confocal microscope image and related table of values for an ethylene chlorotrifluoroethylene (ECTFE) coversheet including a plurality of prismatic structures produced by embossing according to various embodiments taught herein.

FIG. 18 is a block diagram of a power conditioning circuit (PCC) in accordance with an embodiment taught herein.

FIG. 19A is a block diagram of a power conditioning system in a first mode in which the solar cells provide supplemental power for a space-based vehicle.

FIG. 19B is a block diagram of the power conditioning system in a second mode in which the solar cells provide operating power for the space-based vehicle and charge an energy storage device of the space-based vehicle system.

FIG. 20A schematically depicts a side cross-sectional view of an example solar sheet, in accordance with some embodiments taught herein.

FIG. 20B schematically depicts a detail of the solar sheet of FIG. 21A.

FIG. 21 is a perspective view of a solar sheet including a plurality of solar cells illustrating the flexibility of the solar cells and of the solar sheet, in accordance with an embodiment.

FIG. 22 schematically depicts a plan view of an exemplary solar cell, in accordance with an embodiment taught herein.

FIG. 23A schematically depicts a top view of an adhesive layer that includes cutouts smaller than corresponding solar cells, in accordance with some embodiments taught herein.

FIG. 23B schematically depicts a top view an adhesive layer that includes cutouts larger than corresponding solar cells, in accordance with some embodiments taught herein.

FIG. 24 shows a flow chart for a method of assembling a solar sheet as taught herein.

FIG. 25 illustrates a flow chart showing a method of manufacturing a coversheet for a plurality of solar cells for space applications as taught herein.

FIG. 26 illustrates a flow chart showing a method of protecting a plurality of solar cells configured for deployment in space as taught herein.

FIG. 27 illustrates a perspective view of a flexible solar sheet in a state of being rolled up.

FIG. 28 is a Prismatic ray trace model illustrating light propagation from a solar source.

FIG. 29 is an assembly drawing of a textured solar power modules for satellite

### DETAILED DESCRIPTION

In accordance with various embodiments taught herein, systems and methods of the present disclosure include solar sheet devices suitable for space-based applications and having a textured coversheet including prismatic structures that increases light collection efficiency. At the air or vacuum-system interface in any solar sheet system, some amount of light will be reflected according to the Fresnel equations. In a textured coversheet with prismatic structures as taught herein, at least some light that reflects from a first prismatic structure is directed towards a second prismatic structure where it is then directed towards a solar cell surface. Thus, the textured coversheet enables amongst other things “recapture” of light at certain angles that is otherwise lost in conventional planar coversheets.

Systems and methods of the present disclosure including the textured coversheet also greatly simplify the application of dielectric coatings. In space-based applications, a dielectric coating can serve several functions. The dielectric coating can reflect or absorb ultraviolet radiation or low-energy particle radiation (e.g., free protons) to protect components of the solar panel from degradation (e.g., darkening or yellowing). The dielectric coating can also protect a polymer from atomic oxygen attack in low-earth orbit (LEO). The mass of the polymer then protects the solar cell by absorbing some of the proton radiation. Deposition of the dielectric coating on a conventional planar surface creates intrinsic stresses (tensile or compressive) that leads to cracking or wrinkling of the coating, which can degrade performance. The present systems and methods taught herein include a textured coversheet that divides the overlay surface into smaller domains and introduces natural points of stress relief at the edges of the prismatic structures. As a result, intrinsic stress cannot build to a large degree during deposition and the final coating layer is more uniform with reduced cracking and wrinkling.

The textured coversheets are flexible thereby allowing them to flex when they encapsulate the flexible solar cells. One key benefit of the flexibility (imparted by both the encapsulation in this invention as well as our thin-film solar cells) is to enable “roll-up” solar array architectures that can be compactly stowed. They would not collect light while stowed. Another benefit is that the encapsulation is mechanically robust and not prone to breakage, which can happen with standard coverglass encapsulation methods.

The textured coversheets disclosed herein also have a lower achievable mass than other conventional solutions such as coverglass that is used in lower radiation orbits. Additionally, because the textured coversheets can cover multiple solar cells and the corresponding interconnects, the textured coversheets protect the interconnects of the solar cells from atomic oxygen and further protects them from arcing.

As used herein, the term “areal mass” refers to mass per unit area. For example, the areal mass of a solar cell is the mass of solar cell per unit area of the solar cell. As another example, the areal mass of a solar sheet is the mass of solar sheet per unit area of the solar sheet.

As used herein, the term “areal power” refers to power produced per unit area. For example, the areal power of a solar cell is the power produced by the solar cell under a specified illumination divided by the area of the solar cell. As another example, the areal power of a solar sheet is the power produced by the solar sheet under a specified illumination divided by the area of the solar sheet.

As used herein, the term “specific power” refers to the power produced per unit mass. For example, the specific power of a solar cell is the power produced by the solar cell under a specified illumination divided by the mass of the solar cell. As another example, the specific power of a solar sheet is the power produced by the solar sheet under a specified illumination divided by the mass of the solar sheet. The specific power can also be defined as the areal power divided by areal mass.

As used herein, the term “solar sheet” refers to a plurality of solar cells and one or more polymer layers to which the solar cells are affixed or attached. The solar sheet can also include interconnects that electrically connect at least some of the plurality of solar cells. The solar sheet can also include an adhesive that adheres the solar cells to the one or more polymer layers. The solar sheet can also include an adhesive to adhere the solar sheet to an underlying surface (e.g., a surface of a component of a space-based vehicle to which the solar sheet is to be attached). The solar sheet can be flexible to conform to an underlying rounded surface (e.g., the surface of a space-based vehicle).

As used herein, the term “zenith angle” refers to the angle between the zenith and the center of the sun's disc. The zenith angle represents the sun's apparent altitude and is a complementary angle to the “elevation angle.” The elevation angle as used herein refers to the angle between the horizon and the center of the sun's disc. As an example, the zenith angle is approximately 90° and the elevation angle is approximately 0° during a sunrise or sunset.

As used herein, “textured” refers to a surface upon which regular, patterned, random, or periodic structures are formed for the purpose of improving light collection efficiency through the surface.

As used herein, “disposed on” or “disposed over” is not limited to objects in direct contact with but can also encompass a structural relationship including intervening layers.

As used herein, “space-based vehicle” is any object intended for launch, or launched into outer space, or assembled in outer space. As used herein, “outer space” begins at around 100 km above Earth's sea level and includes, but is not limited to, LEO or geosynchronous orbit. As used herein, an object is in “low-Earth orbit” (LEO) when at least a portion of the object's circular or elliptical orbit lies in a range of about 100 km and about 2000 km above Earth's sea level.

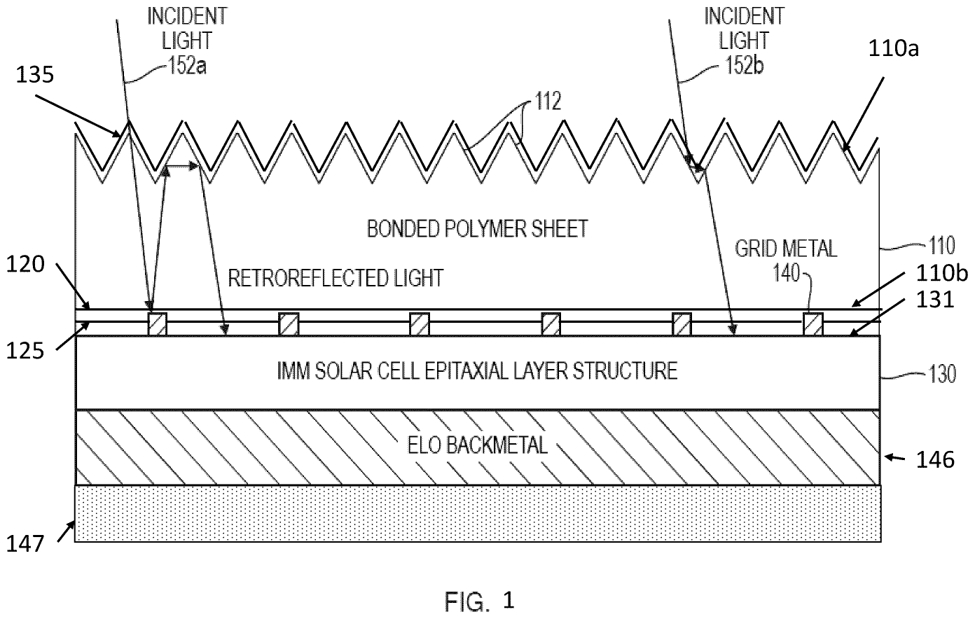

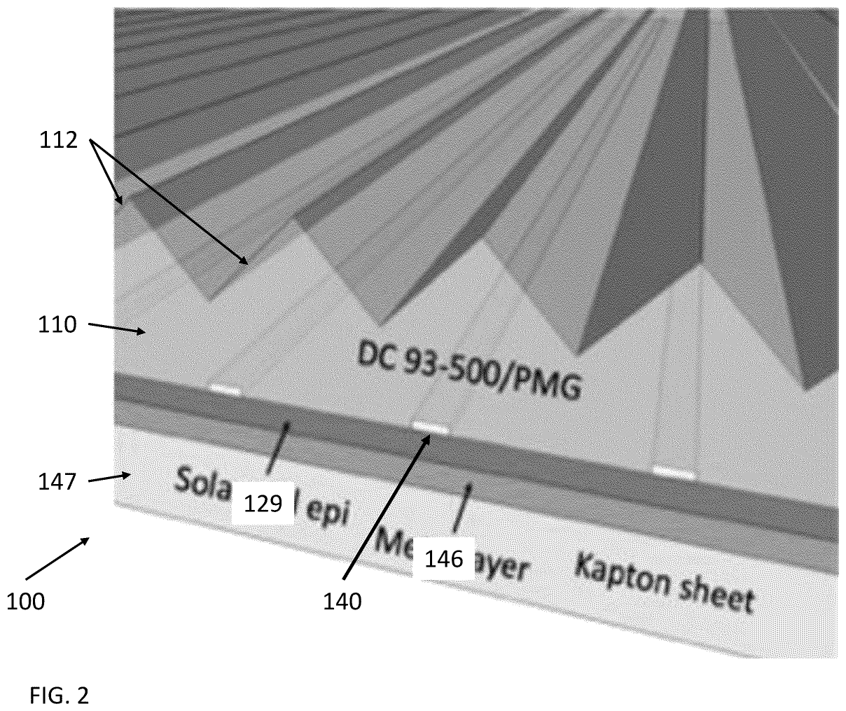

FIG. 1 illustrates a cross-sectional view of a solar sheet 100 with improved light collection efficiency in accordance with various embodiments taught herein. FIG. 2 illustrates a rendered perspective view of another embodiment of the solar sheet 100 as taught herein. The solar sheet 100 includes a flexible coversheet 110 (which in some embodiments can be a polymer sheet) including a textured top surface 110a having surface features or structures. The surface features of the textured top surface 110a can include prismatic structures 112 formed in the top surface 110a (sometimes referred to as the first surface) of the coversheet 110 that forms an air-material interface in some embodiments. In other embodiments, an ultraviolet rejection (UVR) film 135 can be disposed over the coversheet 110. In such embodiments, the top surface of the UVR film 135 can form the air-material interface. The solar sheet 100 also includes an anti-reflection coating 125, one or more thin film solar cells 130, one or more front metal electrodes 140, and one or more back metal electrodes 146. The solar sheet 100 can also include a flexible backing layer 147. A second or bottom surface 110b of the flexible coversheet 110 is disposed over thin film solar cells 130 such that light enters the solar sheet 100 through the flexible coversheet 110 before impinging upon the solar cells 130. In some embodiments, the bottom surface 110b of the flexible coversheet 110 can be attached to the anti-reflection coating 125 using an adhesive layer 120. In some embodiments, the one or more front metal electrodes 140 can connect to the one or more thin film solar cells 130 through a contact layer. The solar cells 130 can be disposed over the back metal electrode 146. When a photon of light impinges on a light-receiving surface 131 of the solar cells 130, the photon can excite a charge carrier due to the photovoltaic effect and produce electricity. The solar sheet 100 with textured coversheet 110 as taught herein provides improved performance (i.e., efficiency) by capturing additional photons and by re-capturing “lost” photons that missed the light-receiving surface 131 of the solar cells 130 or that otherwise did not induce the photovoltaic effect such as by being reflected.

The outward-facing top surface 110a of the flexible coversheet 110 is textured using the prismatic structures 112 to improve transmission of light through the surface 110a and into the solar sheet 100. Each prismatic structure in the plurality of prismatic structures 112 has a particular geometry. The geometry of the prismatic structure can include an inverted prism structure, a non-inverted prism structure (i.e., the structure projects outward from the surface), a corner-cube (i.e., three-sided) prism structure, a pyramidal (i.e., four-sided) prism structure, a linear prism structure, a curvilinear prism structure, or any other suitable one-dimensional or two-dimensional shape. Here, “inverted” refers to a structure that is a depression into the surface while “non-inverted” refers to a structure that projects from the surface. The geometry of the prismatic structure can include curved walls, straight walls, or a combination of curved and straight elements. Embodiments of the textured surface 110a having one-dimensional or linear prismatic structures can include a sidewall topology that varies predominantly in one dimension (e.g., x-direction) across the surface 110a but that does not vary (within manufacturing variances) in the other dimension (e.g., y-direction). Embodiments of the textured surface 110a having two-dimensional prismatic structures can include a sidewall topology that varies in both dimensions (e.g., x and y dimensions). For polygonal prismatic structures, each structure can have three, four, five, or more facets. In some embodiments, the prismatic structures 112 can be at least partially defined by a sidewall angle, which is measured between sidewalls of the prismatic structures 112 and a plane defined by a base on the prismatic structures 112. For the prismatic structure 112 that is analogous to a conic solid such as a pyramid or cone, the sidewall angle is equivalent to an apex angle between a base and a side surface of the conic solid. In some embodiments, the sidewall angle can be in a range between 15° and 75°. In preferred embodiments, the sidewall angle of each prismatic structure 112 can be in a range between 45° and 60°.

FIG. 1 illustrates the recapture and retroreflection of light in a solar cell according to various embodiments taught herein. Retroflection and recapture are additional benefits provided by flexible coversheets including prismatic structures as taught herein. Because of the unique texturing provided by the prismatic structures, light reflected from the solar cell surface can be reflected or recaptured in multiple ways as shown in FIG. 1.

In conventional structures, some light that passes into the coversheet may still be lost due to reflection from the metal grid lines or reflection from the light-receiving surface itself. The active layers 130 of the solar cell are often coated with a multi-layer antireflection coating 125, which reduces but does not eliminate all reflections. In some embodiments, retroreflection may arise when incident light 152a is reflected back from grid lines or the surface of the active layers undergoes total internal reflection at the interface between the flexible coversheet and the surrounding medium (e.g., air). In some embodiments, retroreflection may be achieved by using coversheets made of materials with an index that is higher than silicone such as glass. The light is then redirected back to the active layers 130 where there is another opportunity for absorption. The internal reflection of the light from the prismatic structure shown in FIG. 1 can include reflections from two prism facets, which can be appropriate for high index materials. In other embodiments, the internal reflection of the light includes reflections from three facets (e.g., the “corner-cube prism” effect).

Recapture may arise if incident light 152b reflects from a first prismatic structure on the top surface of the coversheet at a trajectory that causes the light to strike a second prismatic structure where the light can be directed toward the solar cell layers. This recaptured light would have otherwise been lost without the presence of the prismatic structures.

In some embodiments, the prismatic structures 112 can improve light capturing performance at high zenith angles relative to capture performance at low zenith angles. Suitable prismatic structures for improving light capture performance at high zenith angles are described in U.S. Provisional Patent Application No. 63/253,936, filed Oct. 8, 2021, the entire contents of which is incorporated herein by reference. This can be particularly useful in space applications in which body-mounted panels on space-based vehicles do not track the sun. Or in instances in which space-based vehicles do not have attitude control and are tumbling through space. By providing additional chances to capture each photon, the overall loss is reduced and the conversion efficiency is increased. The recapture and retroreflection of photons occurs across the range of zenith angles. In some embodiments, the recapture or retroreflection of photons that can occur at nearly overhead angles (e.g., zenith angles in a range from 0° to 20°) means that the prismatic structures provide an overall improvement in conversion efficiency both when the sun is high in the sky and when the sun is close to the horizon (high zenith angle). In some embodiments, the solar sheet 100 can be mounted on a portion of the space-based vehicle that can rotate, tilt, or otherwise move to position the solar sheet 110 to be facing the sun. Thus, the space-based vehicle of some embodiments can dictate the range of incident angles of light that impinge on the solar sheet 100 such as to position the solar sheet 100 to predominantly receive light at nearly overhead angles (i.e., normal or direct incidence).

In some embodiments, the geometry of each prismatic structure can be identical across the entire flexible coversheet. In some embodiments, the geometry of each of the prismatic structures 112 can be selected individually. In such embodiments, the variation in geometry of prismatic structures 112 can be random or patterned across the sheet. For example, the geometry (including sidewall angle) of the prismatic structures 112 can vary from one end of the solar sheet 100 to the other end or from the ends or perimeter to the middle. For example, the coversheet 110 may have prismatic structures 112 with a large sidewall angle at a first edge of the coversheet (e.g., the first edge is mounted at a leading edge of the space-based vehicle structure) and prismatic structures 112 with a smaller sidewall angle at a second edge of the coversheet opposite the first edge (e.g., the second edge is mounted at a trailing edge of the space-based vehicle structure). The change in sidewall angles transitioning from the first edge to the second edge can be monotonic or non-monotonic and continuous or punctuated. In some embodiments, it may be advantageous to provide a first subset of prismatic structures 112 having a first geometry on portions of the solar sheet intended to lie on flat portions of a space-based vehicle structure and a second subset of prismatic structures 112 having a second geometry on portions of the solar sheet intended to lie on curved portions of the space-based vehicle structure.

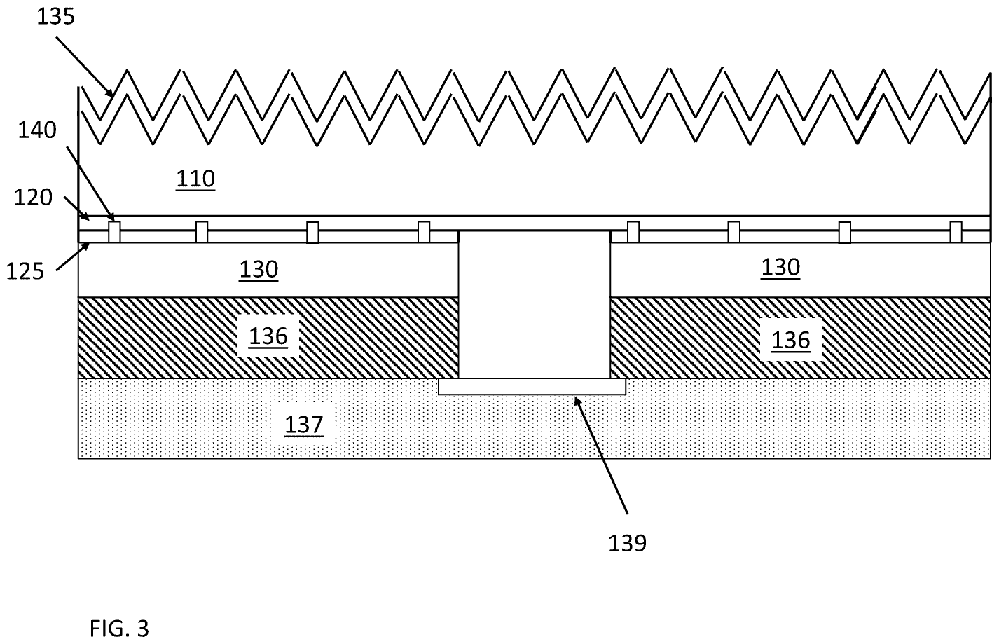

In some embodiments, the coversheet 110 can encapsulate one or more solar cells in the solar sheet. In space applications, front-surface encapsulation can protect the solar cells from radiation or atomic oxygen in the space environment that would otherwise diminish performance of the solar cells. Conventional coversheets can include cerium-doped glass, fused silica, or quartz and are therefore expensive and fragile. Moreover, the coversheet can be applied to individual cells or groups of cells (which are then sometimes termed as Coverglass Interconnected Cells or CIC) that are then joined to form a final solar sheet. A labor-intensive “grouting” process is then performed to seal the space between adjacent solar cells and interconnects between the solar cells. As taught herein, the coversheet 110 can be used for module-level encapsulation wherein the coversheet 110 is applied over multiple interconnected solar cells as described further below in relation to FIG. 3. The module-level encapsulation can be performed with a flexible coversheet 110. Module-level encapsulation can protect the interconnects between solar cells, can help to reduce high-voltage arcing between cells, and can eliminate or reduce the labor-intensive grouting process. In some embodiments, the coversheet 110 can simultaneously encapsulate the solar sheet 100 along a linear dimension in a range from 1 to 200 cm, in a range from 10-100 cm, in range from 10-50 cm, in a range from 50-100 cm, or in a range from 100-200 cm.

In some embodiments, the coversheet 110 and the solar cell layer structure 130 are flexible. In such embodiments, the solar sheet 100 can be rolled up for transport, stowage, or storage. For example, the space-based vehicle may be launched with the solar panels furled and may unfurl the solar panels once orbital altitude has been achieved. In such a case, the flexible solar sheets 100 as taught herein allows the space-based vehicle to condense to a smaller volume for launch and thus reduce payload volume on the launch craft. The radius of the rolled solar sheet 100 including flexible coversheet 110 is smaller than the radius of a rolled solar sheet that include a glass cover layer. In some embodiments, the coversheet 110 as taught herein can improve mechanical robustness of the solar sheet 100, particularly during assembly. Some solar sheets that use a glass cover layer suffer from cracking of solar cells or coverglass as a failure mode during solar panel assembly. Remediation of this cracking can include labor-intensive rework to replace broken cells or coverglass. The flexible coversheet 110 as taught herein can be less brittle than glass cover sheets and can thus be less prone to cracking during assembly or deployment.

The flexible coversheet 110 can be formed of one or more polymer species. In various embodiments, the flexible polymer sheet 110 can be formed of one or more materials selected from the group of fluorinated ethylene propylene (FEP), ethylene tetrafluoroethylene (ETFE), ethylene chlorotrifluoroethylene (ECTFE), and polychlorotrifluoroethylene (PCTFE). The flexible coversheet 110 can include acrylic-based materials in some embodiments. The coversheet 110 can include glass materials in some embodiments. The coversheet 110 can include materials such as polyimides or polydimethylsiloxane (PDMS) in some embodiments. In some embodiments, selection of polymer species for the flexible polymer sheet 110 can be driven by application-specific factors. For example, the polymer species can be selected based on light transmissivity at a particular wavelength or range of wavelengths in some embodiments. In some embodiments, the polymer species can be selected based upon the manufacturing process to be used in processing the flexible polymer sheet 110. Appropriate manufacturing processes can include thermal forming, molding, casting, forming, embossing, roughening, lithographic processes, or other suitable patterning processes. Some manufacturing processes may be more suitable for certain materials. For example, fluorinated ethylene propylene has a relatively high melting temperature (about 260° C.) that may make it difficult to effectively emboss. In some embodiments, roughening techniques can create a matte-like finish with random prismatic surface structures that can enhance light collection as disclosed herein.

In some embodiments, the coversheet 110 can be formed of one or more glass materials including fused silica, quartz, and cerium-doped glass. In some embodiments, the glass coversheet 110 can be formed of segmented glass sheets to reduce fragility and improve flexibility. This parquet format for the coversheet 110 allows the use of glass for encapsulation while avoiding the fragility that can arise with module-sized (i.e., multiple solar cells) sheets.

The prismatic structures 112 can be described in terms of a characteristic dimension in some embodiments. For example, the characteristic dimension can be the distance from a peak of a first prismatic element to a peak of a neighboring prismatic element or can be a length or width dimension corresponding to a base of a pyramidal prismatic structure. The characteristic dimension can be a height of the prismatic structures 112. In some embodiments, the characteristic dimension of the prismatic structures 112 can be longer than a wavelength of incident light 152a, 152b. In some embodiments, the height of each of the prismatic structures 112 can be in a range from approximately 1 micrometers to approximately 100 micrometers. For example, the height of one of the prismatic structures 112 can be measured from a tip or apex to a base of the prismatic structure. In some embodiments, the flexible coversheet 110 is configured to encapsulate the light receiving surface of the plurality of solar cells 130. In some embodiments, the flexible coversheet 110 can have a thickness in a range from approximately 1 micrometers to approximately 1000 micrometers, or in a range from approximately 20 micrometers to approximately 50 micrometers or in a range from approximately 10 micrometers to approximately 150 micrometers. In some embodiments, the thickness of the flexible coversheet 110 can be selected to provide a desired mass density of the solar sheet. Some polymeric materials can be about half as dense as glass, which may impact the thicknesses selected based upon material type. In embodiments intended for space-based applications, the thickness of the flexible coversheet 110 can be, as a non-limiting example, in a range from 50 microns to 500 microns or in a range of 50 to 150 microns or a range of 50 to 250 microns or a range of 200 to 350 microns. Additionally an encapsulation made of silicone can have a thickness within the range of 50-200 microns, and an extended range between 25-1000 microns.

The UVR film 135 can reflect ultraviolet (UV) light, absorb UV light, or both reflect and absorb UV light in various embodiments. UV light can darken the coversheet 110, which can reduce the transparency of the coversheet 110. When the transparency of the coversheet 110 is reduced, the absorption of light by the coversheet 110 is increased and fewer photons pass through the coversheet 110 to impinge on the solar cells 130 and convert to electricity. The UVR film 135 can have high light attenuation for wavelengths below about 350 nm with good light transmission for wavelengths of light above 350 nm. The UVR film 135 can reflect low-energy radiation (such as free electrons or protons), absorb low-energy radiation, or both reflect and absorb low-energy radiation in various embodiments. Low-energy radiation can chemically attack the material (e.g., polymer) of the coversheet 110 such as attack by highly reactive atomic oxygen, which deteriorates the material and ultimately can lead to lower light conversion efficiency or system failure. In particular, atomic oxygen can attack silicon-containing materials and form silicon dioxide (SiO₂), which can decrease light transmission and can cause local changes in surface elastic modulus that lead to cracking. The UVR film 135 can prevent or reduce chemical attack by low-energy radiation. In some embodiments, the UVR film 135 can be disposed over the top surface 110a of the coversheet 110 using electron-beam evaporation or sputter deposition. The UVR film 135 can include a single film layer or multiple film layers. The layers of the UVR film 135 can include one or more oxide-based materials in some embodiments. In some embodiments, the one or more oxide-based materials can include silicon oxide, silicon nitride, titanium oxide, hafnium oxide, aluminum oxide, or niobium oxide. The UVR film 135 can include one or more dielectric materials in some embodiments.

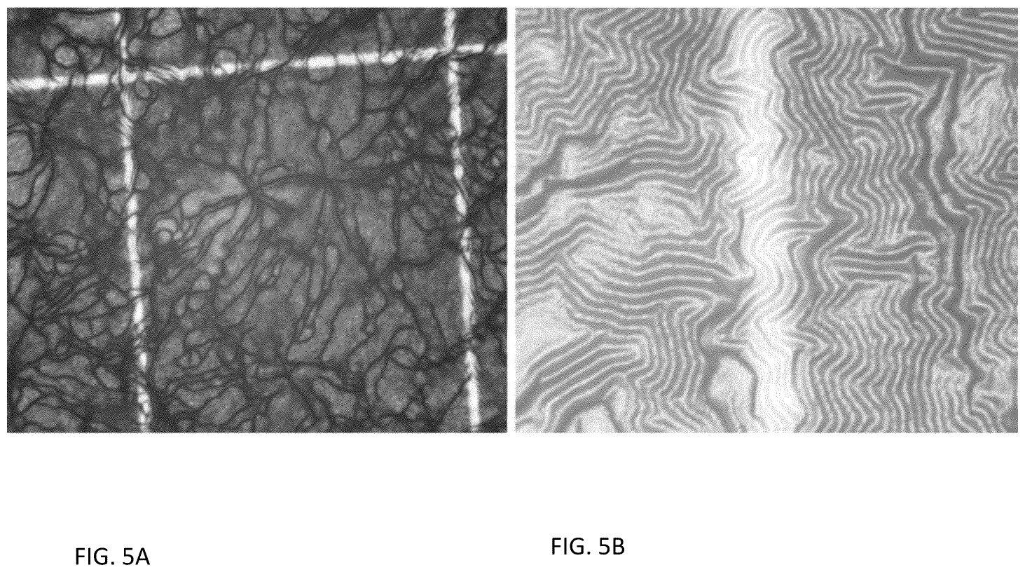

The textured coversheet 110 as taught herein simplifies application of the UVR film 135 to the solar sheet 100. UVR films commonly have intrinsic stresses (whether tensile or compressive) that can lead to cracking or wrinkling of the UVR film during or after application. The stress buildup occurs in part because the UVR film 135 is often a more rigid or inelastic material while the coversheet 110 can be formed of a softer more compressible material such as polymer that can shift or compress as intrinsic stresses build. This cracking or wrinkling degrades solar cell performance and efficiency because discontinuities, folds, or wrinkles in the material are locations where incoming photons can scatter or reflect and thus miss the light-receiving surface 131 of the solar cells 130 where conversion to electricity occurs. As described and shown in detail below in FIGS. 5A-10, the textured coversheet in solar sheets of the present disclosure can alleviate the cracking and wrinkling because the surface 110a of the coversheet 110 is divided into smaller areas or domains. As the UVR film is deposited, the intrinsic stresses cannot build up over long distances because edges of the prismatic structures (e.g., the peaks and valleys) create natural relief points and interrupt stress formation.

The flexible backing layer 147 can cover the solar sheet 100 from beneath the solar cells 130 in some embodiments. In some embodiments, the flexible backing layer 147 can be formed of a polyimide film such as Kapton® (DuPont Corporation) or a polyvinyl fluoride (PVF) material such as TEDLAR® PVF film (DuPont Corporation). In some embodiments, interconnects can be formed on or in the flexible backing layer 147. During assembly, a plurality of solar cells 130 can be aligned and pressed onto the flexible backing layer 147 such that the interconnects facilitate inter-cell connections and provide a pathway for electricity to flow out of the sheet 100. Portions of the flexible backing layer 147 can include an adhesive to adhere the flexible backing layer 147 to the one or more back metal electrodes 146. For example, the adhesive can be a pressure-sensitive adhesive (PSA). A backside adhesive can also be provided on the back surface of the flexible backing layer 147 to enable adhesion or mounting of the solar sheet 100 to a component of the space-based vehicle. The backside adhesive (e.g., PSA) can enable the assembler to “peel and stick” the solar sheet to the space-based vehicle. In some embodiments, the flexible backing layer 147 can include one or more holes or slits to improve flexibility of the layer or to mitigate against entrapped air during assembly by providing egress routes for the air away from the edges of the solar sheet 100.

FIG. 3 illustrates a cross-sectional view of two neighboring solar cells 130 in the solar sheet 100 according to various embodiments taught herein. The coversheet 110 is disposed over the plurality of solar cells 130 and interconnects 139 between the solar cells 130. The interconnects can create serial or parallel electrical connections between solar cells 130 and enable electricity to be drawn out of the solar sheet 100 to, for example, a power conditioning system. In this figure, the interconnects 139 are printed or embedded in the flexible polymer layer 137. Encapsulating a large portion or all of the solar sheet 100 with the textured coversheet 110 as taught herein leads to encapsulation of multiple solar cells 130 and the interconnects 139 between solar cells 130 simultaneously. This method of assembly avoids the need for “grouting” to seal the areas between adjacent cells when cover glass is applied individually (i.e., in CIC cells). In some embodiments, the interconnects 139 between solar cells 130 are between the grid metal on a solar cell and a ELO back metal on another solar cell.

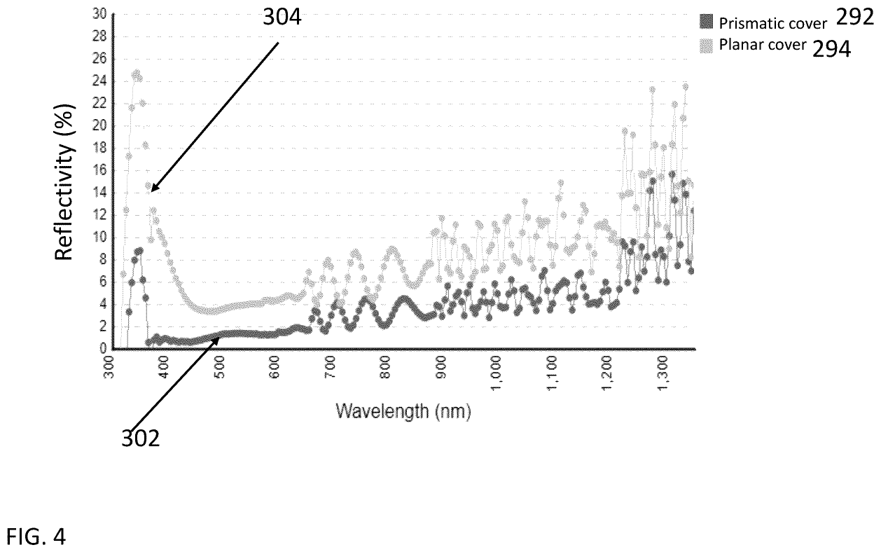

FIG. 4 illustrates a comparison of the measured surface reflectivity as a function of wavelength of light from a solar sheet 100 including a textured coversheet with prismatic structures as taught herein and a conventional solar sheet with a planar coversheet. The reflectivity curve 302 for the solar sheet 100 as taught herein is lower than the reflectivity curve 304 for conventional solar sheets across much of the wavelength spectrum. In some embodiments, the solar sheet 100 including the textured coversheet with prismatic structures 112 can have at least a 3% reduction in reflection across all wavelengths as compared to the conventional solar sheet.

FIGS. 5A and 5B show top views of a conventional solar sheet with a planar coversheet formed of silicone with a UVR coating at lower and higher magnifications, respectively. In the depicted sheets, the UVR coating layer was deposited using electron beam (e-beam) deposition techniques. In the lower magnification image (FIG. 5A), the surface has a crazed or spider-webbed appearance. In the higher magnification image (FIG. 5B), it is apparent that the UVR layer has extensive wrinkling. This wrinkling can cause diffractive losses or worsen the reflectivity of the surface.

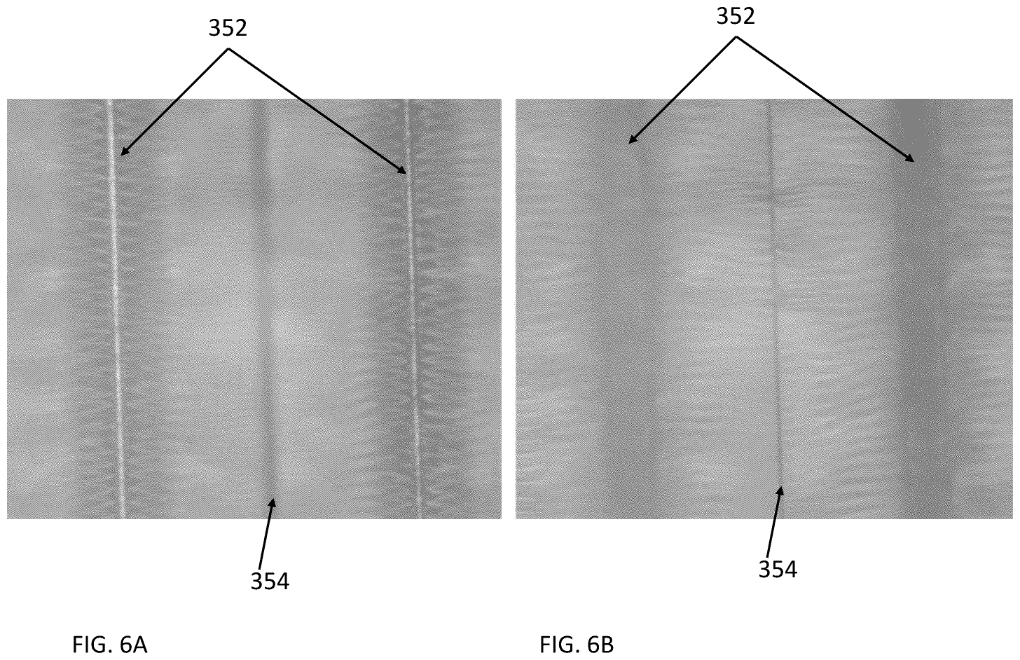

FIGS. 6A and 6B show top views of the solar sheet 100 with textured coversheet as taught herein with a UVR coating at two different focal depths. The thickness of the UVR coating can be within a range of circa 0.3 microns. In this case, the prismatic structures 112 have a characteristic dimension of 175 micrometers and are linear (i.e., one-dimensional), and the coversheet is formed of silicone. In the figures, peaks 352 of different prismatic structures 112 and valleys 354 between the structures 112 are visible. In FIG. 6A, the peaks 352 are in focus while the valley 354 is in focus in FIG. 6B. Unlike the surface shown in FIGS. 5A and 5B, minimal or no wrinkling is observed.

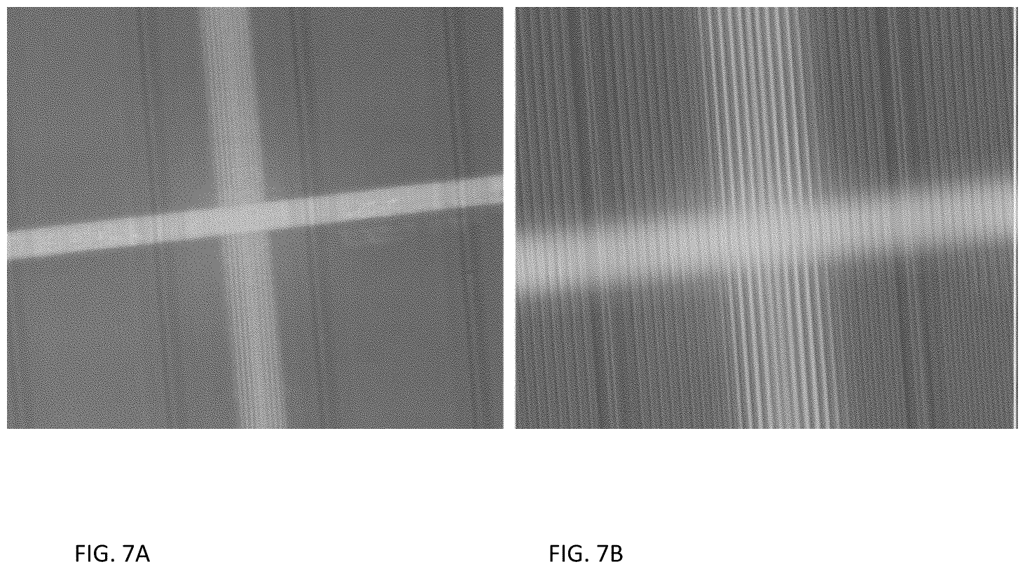

FIGS. 7A and 7B show top views of the solar sheet 100 with a textured coversheet with a UVR coating as taught herein at lower and higher magnification, respectively. In this case, the prismatic structures 112 have a characteristic dimension of 3 micrometers and are linear (i.e., one-dimensional), and the coversheet is formed of silicone. Unlike the surface shown in FIGS. 5A and 5B, minimal or no wrinkling is observed.

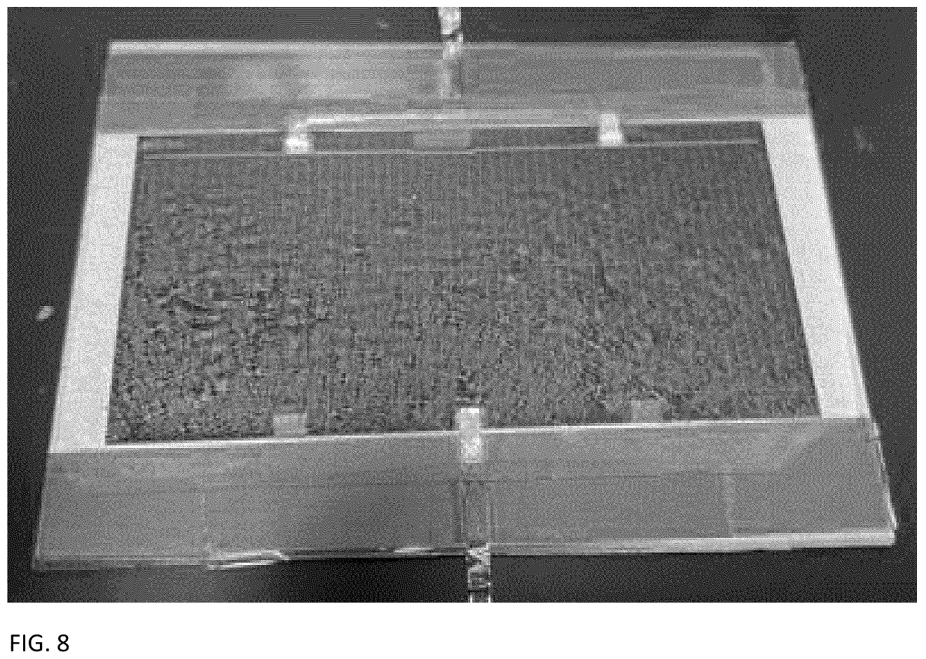

FIG. 8 is an image of a solar sheet with a planar coversheet illustrating the poor surface quality. The wrinkling and spider webbing of the UVR coating creates an apparent color shift.

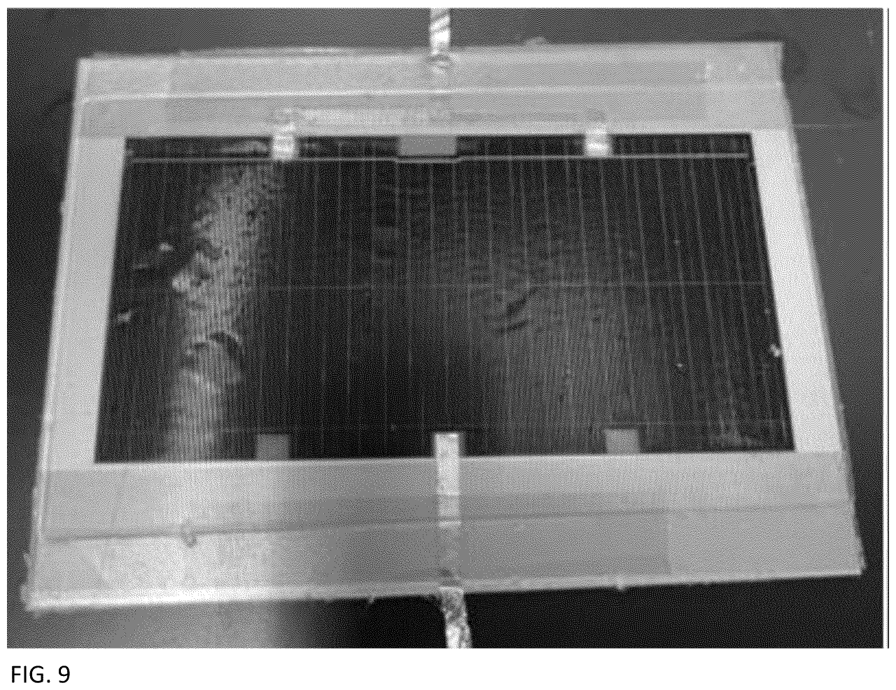

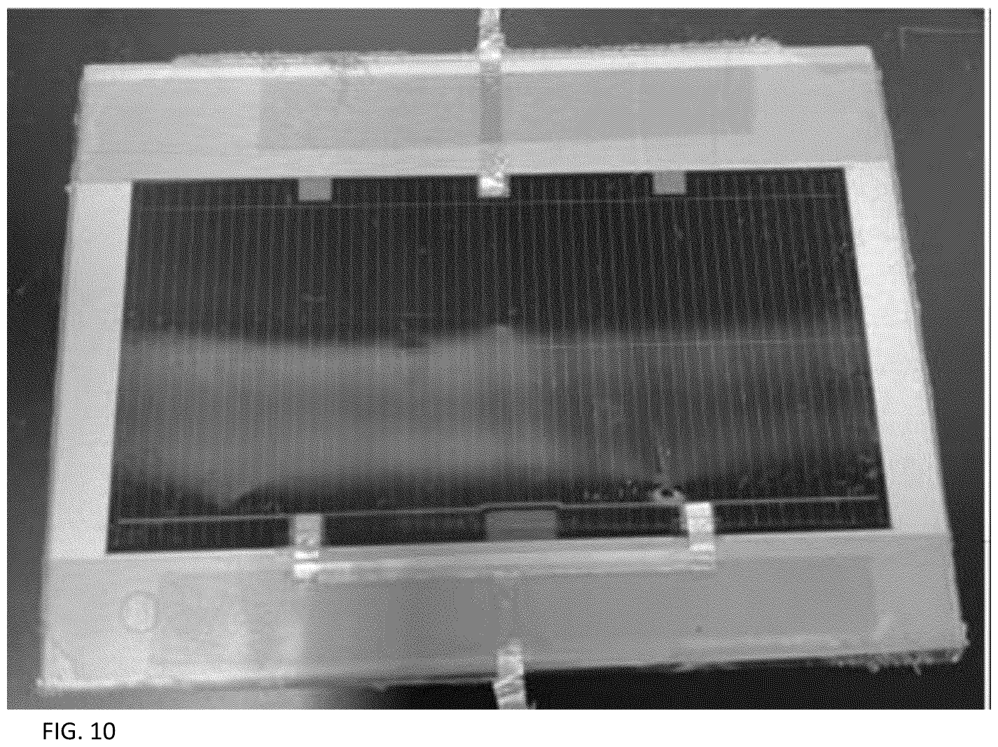

FIGS. 9 and 10 illustrate solar sheets 100 with textured coversheet having prismatic structures 112 with characteristic dimensions of 175 micrometers and 3 micrometers, respectively. The coversheet with UVR coating is substantially transparent with little discoloration as evidenced by the fact that the solar cells are clearly visible.

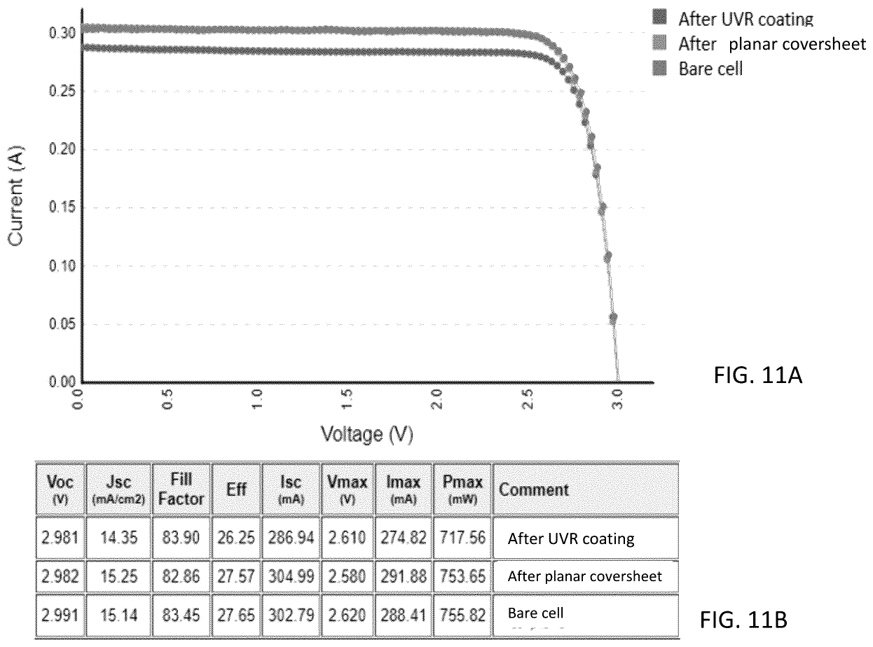

FIG. 11A illustrates current-voltage (I-V) curves for a conventional solar sheet with planar coversheet at three stages of manufacture: solar sheet of bare cells, solar sheet with planar coversheet, and solar sheet with UVR coating disposed over the planar coversheet. FIG. 11B is a table of relevant parameters for the solar sheet at the three stages including open circuit voltage, current density, fill factor, efficiency, short circuit current, maximum voltage, maximum current, and maximum power. In FIG. 11A, the conventional solar sheet with planar coversheet and UVR coating experiences a 6% drop in current as compared to the bare solar cells or the solar sheet with the planar coversheet. The reduction arises from the poor surface quality (e.g., wrinkling) as well as intrinsic Fresnel reflection (about 2.9%).

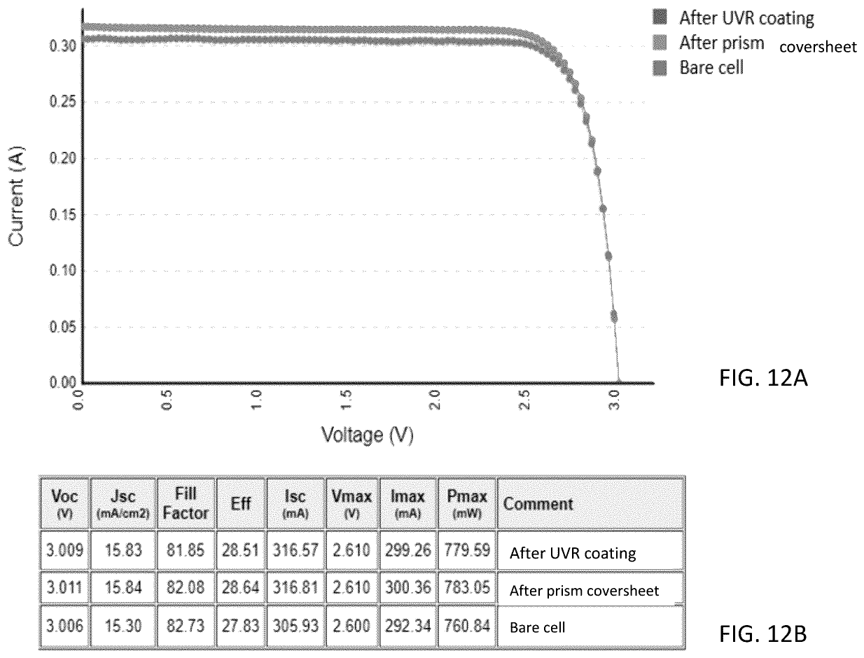

FIG. 12A illustrates I-V curves for a solar sheet 100 with textured coversheet including prismatic structures at three stages of assembly: solar sheet of bare cells, solar sheet with textured coversheet, and solar sheet with UVR coating disposed over the textured coversheet. The coversheet 110 has linear prismatic structures 112 with a characteristic distance of 175 micrometers. FIG. 12B is a table of relevant parameters for the solar sheet at the three stages of assembly including open circuit voltage, current density, fill factor, efficiency, short circuit current, maximum voltage, maximum current, and maximum power. In FIG. 12A, the solar sheet 100 with coversheet 110 and UVR film 135 experiences a 3.5% increase in current as compared to the bare solar cells. Notably, the measurements for the solar sheets 100 with and without the UVR film 135 are nearly indistinguishable, which indicates that the UVR film has not significantly wrinkled or disrupted optical transmission in this case.

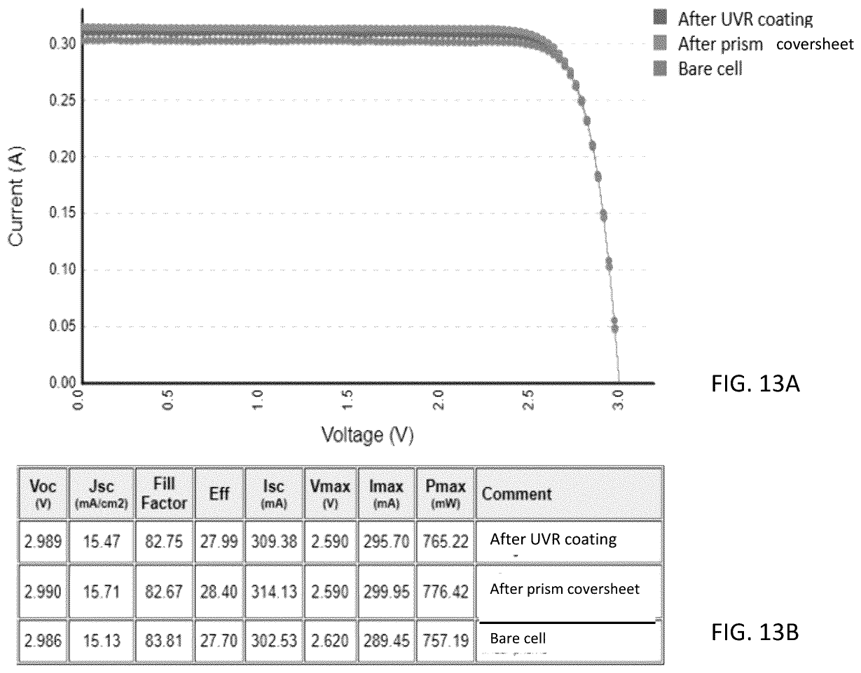

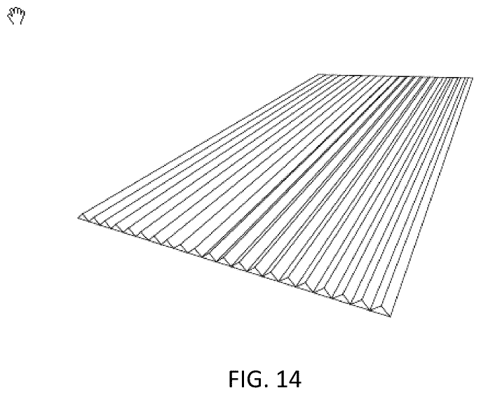

FIG. 13A illustrates I-V curves for a solar sheet 100 with textured coversheet including prismatic structures at three stages of assembly: solar sheet of bare cells, solar sheet with textured coversheet, and solar sheet with UVR coating disposed over the textured coversheet. The coversheet 110 has linear prismatic structures 112 with a characteristic distance of 3 micrometers. FIG. 13B is a table of relevant parameters for the solar sheet at the three stages of assembly including open circuit voltage, current density, fill factor, efficiency, short circuit current, maximum voltage, maximum current, and maximum power. In FIG. 13A, the solar sheet 100 with coversheet 110 experiences a 3.5% increase in current as compared to the bare solar cells. The solar sheet 100 with coversheet 110 and UVR film 135 then has a 1.5% drop from the values without the UVR film 135. The drop in current after application of the UVR film 135 may indicate that depositing the UVR film 135 on prismatic structures 112 with larger characteristic dimension is more straightforward. Nevertheless, the overall efficiency is still improved by 2% over the bare cells with no coversheet, and the presence of the UVR film 135 can protect the solar sheet 100 against UV and chemical degradation in outer space.

Generally, the number of solar sheets to be installed on a space-based vehicle depends on various factors, (e.g., size of the space-based vehicle, size of each solar sheets, how many solar cells are incorporated into each solar sheet). In some embodiments, the number of solar cells used on a space-based vehicle can be 100, 200, 300, 400, 500, 600, 700, 800, 900, or about 1000. In some embodiments, the number of solar cells used on a space-based vehicle can be 1,000, 2,000, 3,000, 4,000, 5,000, 6,000, 7,000, 8,000, or about 9,000. In some embodiments, the number of solar sheets used on a space-based vehicle can be more than 10,000. In some embodiments, the number of solar sheets used on a space-based vehicle falls in a range of 100 to 1,000 solar sheets, 100 to 1,500 solar sheets, or 1,000 to 10,000 solar sheets. An array of solar cells for satellites can vary in size from ten watts for cube satellites (also referred to as nano satellites) to tens of kilowatts or more or larger satellites.

FIG. 14 illustrates a three-dimensional rendering of multiple linear prismatic structures. Linear prismatic structures may offer greater ease of manufacturability as compared to other prismatic structures in some embodiments as the “mold” used to form linear prismatic structures is relatively straightforward to machine. Additionally, the dimensions of linear prismatic structures may scale to thinner sheet materials more readily than other prismatic structures and thereby enable reduction of the overall weight of the structure. In some embodiments, linear prismatic structures may be easier to clean because their structural configuration avoids small-dimension “pockets” that can collect dust or debris.

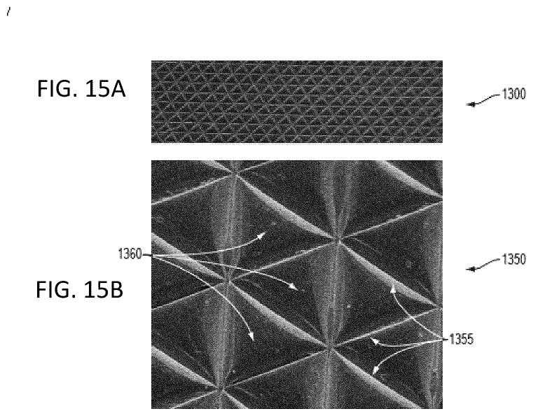

FIGS. 15A and 15B include SEM images 1300 and 1350 at different magnification factors of a polymer sheet with a textured surface (e.g., an embodiment of the polymer sheet 110) formed of fluorinated ethylene propylene (i.e., a variant of Teflon®) and including prismatic structures (e.g., an embodiment of the prismatic structures 112) according to various embodiments taught herein. The polymer sheet was prepared in this example using an embossing technique. The polymer sheet can allow optical transmission well into the ultraviolet (extending to at least 350 nm), which can correspond to the spectral bandwidth of the associated solar cells in some embodiments. In some embodiments, the polymer sheet can have high optical transmission in a wavelength range from approximately 350 nm to approximately 1300 nm or in a range from approximately 300 nm to approximately 1800 nm. The polymer sheet can be laminated onto the solar cell using a silicone-based pressure-sensitive adhesive in some embodiments. For the polymer sheet depicted in FIGS. 15A and 15B, the prismatic structures are three-sided positive pyramid structures. The valleys 1355 between the pyramids are sharply defined, but the apexes 1360 of the pyramids are rounded-off rather than forming sharp peaks.

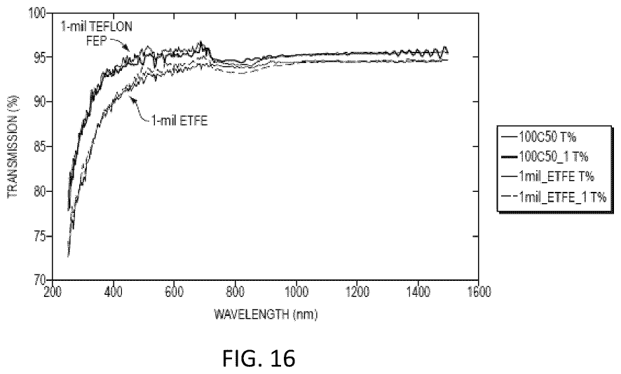

Embodiments of the flexible polymer sheet (e.g., embodiments of the polymer sheet 110) can be formed of one or more materials. The material(s) can be selected to impart particular desirable properties such as optical transmissivity at particular wavelengths or wavelength ranges, enhanced durability, or enhanced machinability in forming the prismatic structures. In some embodiments, the materials can include one or more selected from the group of fluorinated ethylene propylene (FEP), ethylene tetrafluoroethylene (ETFE), ethylene chlorotrifluoroethylene (ECTFE), and polychlorotrifluoroethylene (PCTFE). ETFE and ECTFE in particular are fluorinated polymers with optical transmission over a wide range of wavelengths as well as high durability and resistance to degradation under long-term ultraviolet light exposure. FIG. 16 shows the measured optical transmission as a function of wavelength for 1 mil-thick sheets of both Teflon FEP and ETFE. At shorter wavelengths (below 600 nm), the ETFE has moderately lower transmission than Teflon FEP, but this difference is expected to be acceptable for many applications. Increased absorption at short wavelengths may be a trade-off for other features such as durability in thicker coversheets (i.e., 3-4 mil). In some embodiments, the transmissivity of the polymer sheet 110 can be greater than 95% for wavelengths of light in the range from 400 to 1500 nanometers.

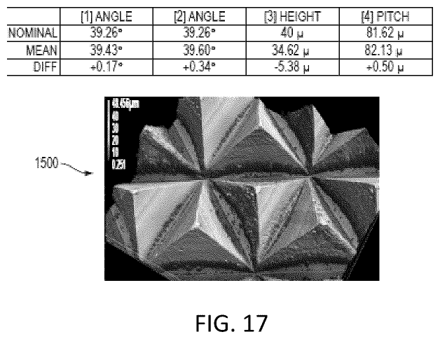

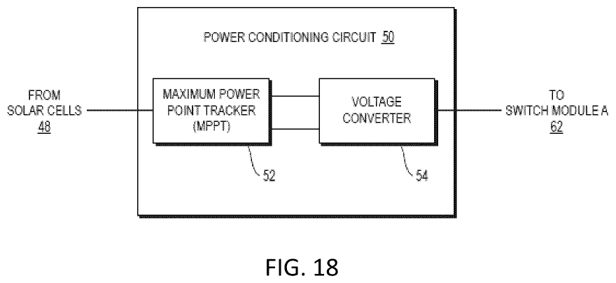

FIG. 17 illustrates a scanning laser confocal microscope image 1500 and related table of values for an ethylene chlorotrifluoroethylene (ECTFE) coversheet including a plurality of prismatic structures produced by embossing according to various embodiments taught herein. The prismatic structures are three-sided positive pyramid structures. After optimization of embossing process parameters, high-quality prismatic patterns were transferred into the ECTFE material and ETFE (not shown). A total of twenty-five measurements were carried out across five different samples to generate the data table shown, which includes measured geometric parameters for the pyramids (two different angles, height and pitch). The pyramids were well defined and uniform. Similar results were obtained for ETFE materials.

The plurality of solar cells 130 may be single-junction solar cells, multi-junction solar cells (e.g., dual-junction solar cells, triple junction solar cells) or any combination of single-junction solar cells and multi-junction solar cells. Although triple junction solar cells generally have a higher efficiency than that of single junction or dual-junction solar cells, triple junction solar cells are generally more complicated to produce and may have a narrower wavelength range for high efficiency performance. The efficiency of the dual-junction and single-junction cells is less sensitive to the spectrum of the incident light than that of a triple-junction cell, so more energy may be obtained from dual-junction or single-junction cells when the cells are exposed to scattered light, rather than to direct sunlight. Accordingly, in some embodiments it may be desirable to use dual-junction or single-junction cells on the underside of the wings or the fuselage where the ratio of scattered light to direct sunlight is greater than for a top side of the wings.

The solar cells 130, and any solar sheets 100 into which the solar cells 130 are incorporated, must be flexible to conform to an underlying curved shape of a surface of space-based vehicle or of a space-based vehicle component onto which they will be mounted or into which they will be incorporated. For example, flexible solar sheets including flexible solar cells can be furled and stowed until the vehicle is fully deployed in orbit. Further, flexible solar cells can be more durable than similar non-flexible or less flexible (i.e., more brittle) solar cells during installation, and during use.

The solar cells and the solar sheets that include the solar cells can have a total mass that is relatively small compared to the mass of the space-based vehicle and can have a relatively low mass per unit area.

For a given solar cell, the efficiency for one spectrum of light is generally different from the efficiency for another spectrum of light. Parameters that depend on the efficiency of the solar cell can be specified for different types of illumination. For example, the specific power of solar cells or solar sheets can be specified under air mass coefficient 1.5 (AM1.5) light, which is typically used to characterize low altitude or terrestrial based solar cells. The specific power of solar cells or solar sheets can alternatively or additionally be specified under air mass coefficient 0 (AM0) light, which corresponds to high altitude conditions or light conditions above the atmosphere.

Various types of commercially available solar cells as well as ELO dual junction (i.e., lattice-matched) (InGaP-GaAs) solar cells, ELO IMM triple-junction (i.e., meta metamorphic) ((Al) InGaP/GaAs/InGaAs) solar cells and IMM cells with more than three junctions made by MicroLink Devices, Inc. can be used in conjunction with embodiments of the present disclosure. In some embodiments, aluminum can be included in the first junction (e.g., AlInGaP/GaAs/InGaAs). In some embodiments, aluminum was not included in the first junction (e.g., InGaP/GaAs/InGaAs) depending on the application or use. For example, the triple-junction InGaP/GaAs/InGaAs solar cell performs well under AM1.5. However, under AM0, AlInGaP/GaAs/InGaAs can be used because the aluminum can help the first junction to be better tuned to the high UV content of AM0 as compared to AM1.5.

Commercially available solar cells include single-junction polycrystalline silicon solar cells, single-junction single crystal silicon solar cells, triple junction and four junction gallium arsenide solar cells on germanium, triple-junction solar cells on germanium, and single-junction copper-indium-gallium-selenide (CIGS) solar cells. Both polycrystalline silicon solar cells and single crystal silicon solar cells are rigid solar cells, (i.e., not flexible solar cells). CIGS solar cells are grown on glass, polymers and metal sheets. CIGS solar cells are flexible, but they typically have a lower efficiency compared to silicon or GaAs-based solar cells. GaAs solar cells, which are grown on a Ge substrate, are both rigid and fragile; however, due to their high efficiency, they are often used for space solar arrays.

In some embodiments not including textured coversheets, a specific power of the plurality of solar cells is at least a threshold value (e.g., at least 1000 W/kg, at least 1500 W/kg, at least 2000 W/kg, at least 2500 W/kg, for AM1.5). The threshold value may alternatively, or additionally be specified with respect to AM0 (e.g., at least 1220 W/kg, at least 1870 W/kg, at least 2520 W/kg, or at least 3150 W/kg, under AM0). In some embodiments, the specific power of the solar cells falls within a specified range (e.g., 1000-4500 W/kg, 1500-4500 W/kg, 2000-4500 W/kg, 2500-4500 W/kg, or 1500-6000 W/kg under AM1.5). The range may alternatively, or additionally, be specified with respect to AM0 light (e.g., 1220-5680 W/kg, 1870-5680 W/kg, 2520-5680 W/kg, 3150-5680 W/kg, or at least 1870-7000 W/kg, under AM0).

The specific power of a solar cell depends on the efficiency of the solar cell (electrical energy produced divided by solar energy absorbed for a unit area of the solar cell) and the mass per unit area of the solar cell (i.e., the areal mass). Thus, a solar cell with a relatively high specific power has a relatively high efficiency and/or a relatively low areal mass. Solar cells free of a substrate (e.g., solar cells produced using epitaxial lift off (ELO)) may be particularly well suited for use on a space-based vehicle because they have a reduced mass per unit area and greater flexibility as compared to solar cells attached to an underlying substrate.

In general, if the materials of a solar cell remain the same, decreasing the thickness of the solar cell increases the flexibility of the solar cell. As noted above, increased flexibility allows the solar cell to be rolled up and increases the durability of the solar cell. In some embodiments, the solar cell (including components thereof such as the flexible polymer sheet) can flex in two dimensions to a bend radius to within a range of 1 to 2 inches. In some embodiments, each solar cell may have a thickness of less than a specified thickness (e.g., less than 40 μm, less than 25 μm, less than 13 μm, or less than 5 μm). In some embodiments, each solar cell may have a thickness that falls in a specified range (e.g., 2-40 μm, 2-30 μm, 2-15 μm).

The areal mass of a solar cell is independent of the light spectrum used for power generation (i.e., AM1.5 or AM0). In some embodiments, the areal mass of a solar cell may have a value that falls in a specified range (e.g., 70-280 g/m², 165-250 g/m², 95-165 g/m², 70-95 g/m²). The areal mass of the solar cell can be reduced by reducing the mass of one or more components of the solar cell without reducing the area of the solar cell. For example, for solar cells that include a backing layer, such as ELO (latticed matched and or metamorphic) solar cells including a backing layer, reducing the thickness of the backing layer of the solar cell can reduce the areal mass of the solar cell. In some embodiments, the solar cell includes a metal backing layer. In some embodiments, the metal backing layer 146 may have a thickness of less than a specified thickness (e.g., less than 30 μm, less than 15 μm, or less than 5 μm). In some embodiments, the backing layer 146 can include metal and polymer.

Areal power of a solar cell is dependent on the efficiency of the solar cell. The areal power of a solar cell is greater under AM0 than under AM1.5. This is due to the fact that AM0 light inherently has more power to begin with because, unlike the AM1.5 light, the AM0 light has not been filtered by atmospheric conditions. In some embodiments, the efficiency of the solar cells under AM0 varies by 2.5% from efficiency of the solar cells under AM1.5. For example, if the solar cell has 25% efficiency under AM0, it has about 27.5% efficiency under AM1.5. In some embodiments, the solar cell has 29% efficiency under AM1.5 that results in an areal power of 290 W/m² under AM1.5, and the solar has 26.5% efficiency under AM0 that results in an areal power of 360 W/m² under AM0. In another embodiment, the efficiency of the solar cell can increase to 30% under AM0 resulting in an areal power of 410 W/m² under AM0 and as a result, the efficiency of the solar cell can increase to 32.5% under AM1.5 resulting in an areal power of 325 W/m² under AM1.5.

In some embodiments, the areal power of the solar cell may be in the range of 260-360 W/m² under AM1.5. In some embodiments, the areal power of the solar cell may be in the range of 325-450 W/m² under AM0.

As noted above, at least some solar cells (e.g., embodiments of solar cells 130) may be incorporated into a flexible solar sheet (e.g., embodiments of solar sheets 100). For example, in some embodiments, lightweight solar cells (or strings of solar cells) are disposed under a polymer film or between polymer films to form flexible solar sheets to aid in easier handling and installation, and to provide greater protection of the solar cells. The flexible solar sheets conform to curved surfaces.

The areal mass of a solar sheet includes the encapsulating materials that form the solar sheet ready to be installed on a space-based vehicle. As noted above, decreasing the mass of solar sheet increases the specific power of the solar sheet. The main factor for reducing the areal mass of the solar sheet is the reduction in thickness of the encapsulating materials by substituting lighter materials and eliminating redundant materials. In some embodiments, the areal mass of the solar sheet may have a value that falls in a specified range (e.g., 120-570 g/m², 120-300 g/m², or 120-160 g/m²).

The areal power of a solar sheet is dependent on the efficiency of the solar cells in the solar sheet as well as how tightly the solar cells are packed together in an array in a solar sheet. One way to increase the areal power of the solar sheet is by reducing or minimizing the spacing or the lateral gaps between adjacent solar cells in the solar sheet. In one embodiment, the solar cells were spaced 2 mm or more from each other resulting in a sizable amount of area on the solar sheet that was not active and did not contribute power to the whole solar sheet. The areal power of the solar sheet was measured to be 230 W/m² under AM1.5. In another embodiment, the solar cells were packed with less than 1 mm spacing between adjacent cells. The areal power of the solar sheet was measured to be 260 W/m² under AM1.5 and 330W/m² under AM0.

Solar cells used with embodiments employing solar sheets may be based on any number of suitable semiconductor materials like III-V semiconductor materials (e.g., GaAs-based materials, InP-based materials, etc.) and Si-based materials. The solar cells may be single junction solar cells, multi-junction solar cells (e.g., double-junction, triple-junction), or a combination of single junction and multi-junction solar cells. In general, higher efficiencies can be obtained with multi-junction solar cells than with single junction solar cells, however, multi-junction solar cells are more complicated to make and can be more expensive. Examples of solar cells having relatively high efficiencies include triple junction inverted metamorphic (IMM) solar cells, which may be produced using ELO or using methods that do not employ ELO. As a specific example, triple junction IMM solar cells with an (Al) InGaP/GaAs/InGaAs grown inverted on GaAs by the inventors demonstrated efficiencies of greater than 30% under AM0.

Further information regarding III-V semiconductor solar cells produced by ELO (e.g., single junction, multi-junction and IMM solar cells), and how to manufacture III-V semiconductor ELO solar cells may be found in U.S. Pat. No. 7,994,419 to Pan et al. issued Aug. 9, 2011, which is incorporated by reference herein in its entirety. Further information regarding InP-based solar cells produced by ELO (single junction, multi-junction and IMM) and how to manufacture InP-based ELO solar cells may be found in U.S. patent application Ser. No. 13/631,533, filed Sep. 28, 2012, which is incorporated by reference herein in its entirety.

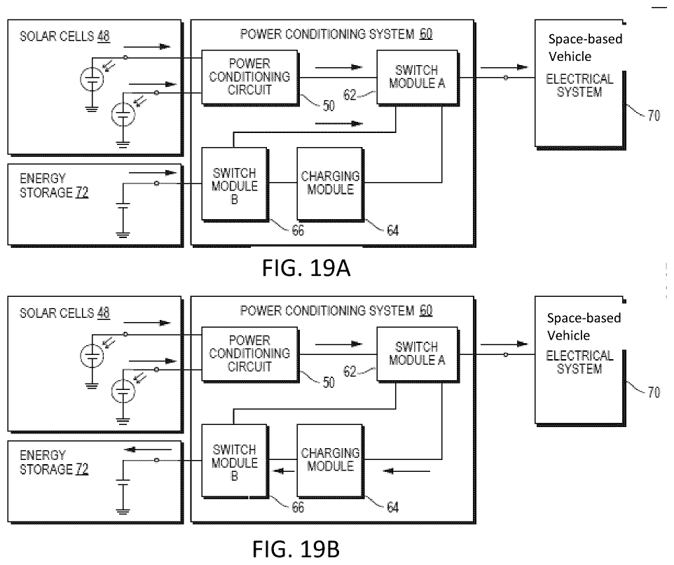

FIG. 19 is a block diagram of a power conditioning circuit 50 included in the power conditioning system in accordance with some embodiments. The power conditioning circuit 50 includes a maximum power point tracker (MPPT) 52 connected with the solar cells. The MPPT 52 is configured to operate the solar cells within a desired power range. Any type of suitable MPPT component or circuit may be employed. The power conditioning circuit also includes a voltage converter 54 that converts voltage from the MPPT into a voltage compatible with the electrical system of the space-based vehicle. Any suitable voltage conversion component or circuit may be employed (e.g., a buck voltage converter (DC-to-DC voltage reduction), a boost voltage converter (DC-to-DC voltage increase)). In this embodiment, the voltage converter 54 is connected to an electrical system of the space-based vehicle through a switch (switch A 62).

In some embodiments, the power conditioning system may also be configured to charge an energy storage device (e.g., a battery, fuel cell) of the space-based vehicle. FIGS. 19A and 19B are block diagrams representing a power conditioning system 60 configured to charge an energy storage device of the space-based vehicle in accordance with some embodiments. Power conditioning system 60 includes the power conditioning circuit 50 and switch module A 62, which connects with the space-based vehicle electrical system 70. As shown, power conditioning system 60 may also include a charging module 64 and a switch module B 66 that connect with an energy storage clement 72 (e.g., a battery, fuel cell) of the space-based vehicle.

In FIG. 19A depicts a block diagram of a power management system for an example space-based vehicle operating in a first mode in which the solar cells 48 supply just a portion of the power being used by the space-based vehicle electrical system 70. In this mode, through switch module B, the energy storage device 72 (e.g., battery, fuel cell) supplements the power supplied by the solar cells for the space-based vehicle's electrical system 70. As indicated by arrows, the charging module 64 is bypassed in this mode. In FIG. 19B, the system is operating in a second mode in which the power supplied by the solar cells 48 exceeds the power being used by the space-based vehicle electrical system 70 and the excess generated power is directed through the charging module 54 and switch module B 66 to charge the energy storage 72 (e.g., battery, fuel cell). A third mode of operation in which the power supplied by the solar cells exactly matches the power used by the electrical system is not depicted because, generally speaking, the third mode only occurs when shifting from the first mode to the second mode and vice-versa). In some embodiments, a space-based vehicle incorporating a secondary solar power system can be charged with exposure to sunlight before flight as well as during flight.

Electrical connections (e.g., power bus lines, wiring harness) connecting the solar cells, the power conditioning system, the electrical system of the space-based vehicle and the energy storage device (e.g., battery, fuel cell) of the space-based vehicle may be integrated into one or more components of the space-based vehicle.

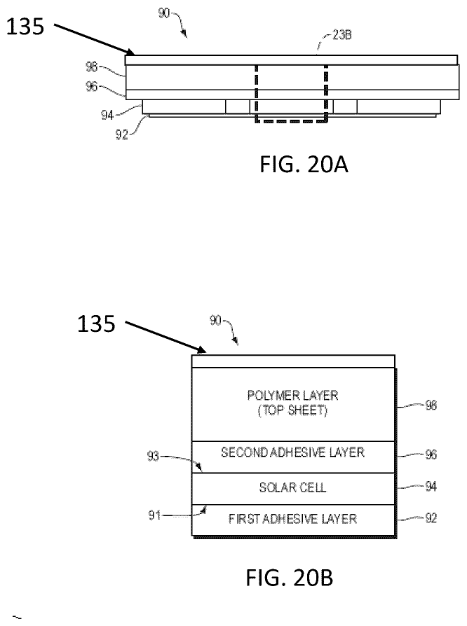

FIG. 20A schematically depicts a side cross-sectional view of a solar sheet 90 for installation on a component of a space-based vehicle in accordance with an embodiment. FIG. 20B is a detail view of FIG. 20A. The solar sheet 90 includes a plurality of solar cells 94 each having a top surface 93 and a bottom surface 91. The solar sheet 90 can include any form of the plurality of prismatic structures as taught herein. Solely for illustrative purposes, the cross-section of solar sheet 90 is depicted with three solar cells. In some embodiments, the solar sheet 90 may have more than three columns or more than three rows of solar cells. In some embodiments, the solar sheet may have less than three columns or less than three rows of solar cells. In FIGS. 20A and 20B, interconnects between the solar cells are not shown for clarity. In some embodiments, each of the solar cells has a specific power in a range of 1500-4500 W/kg under AM1.5 or a specific power in a range of 1870-5680 W/kg under AM0. In some embodiments, each of the solar cells has a specific power in a range of 2000-4500 W/kg under AM1.5 or a specific power in a range of 2520-5680 W/kg under AM0. In some embodiments, each of the solar cells has a specific power in a range of 2500-4500 W/kg under AM1.5 or a specific power in a range of 3150-5680 W/kg under AM0.

The solar sheet 90 also includes a polymer layer 98 to which the plurality of solar cells 94 are attached. The polymer layer 98 can be planar (as depicted in FIG. 20B) or can include prismatic structures in accordance with embodiments described above. As depicted, the polymer layer 98 is attached to the top surface 93 of the solar cells and may be described as a polymer top sheet. In some embodiments, the polymer layer 98 includes polytetrafluoroethylene, e.g., TEFLON® from DuPont. In some embodiments, a thickness of the polymer layer 98 is in a range of 15 microns to 30 microns.

In some embodiments, the solar sheet 90 includes a first adhesive layer 92. In some embodiments, the first adhesive layer 92 is configured to attach the solar sheet 90 to a component of a space-based vehicle. In some embodiments, the first adhesive layer 92 is in contact with a bottom surface 92 of each solar cell. The adhesive of the first adhesive layer 92 can be a RTV silicone, which, in turn, is bonded to a Kapton back sheet. In some embodiments, the thickness of the first adhesive layer 92 is in a range of 8 microns to 15 microns. In some embodiments, the thickness of the first adhesive layer is in a range of 8 microns to 25 microns. In some embodiments, the bottom surface 91 of each of the solar cells 94 is in contact with the first adhesive layer 92.

In some embodiments, the solar sheet 90 includes a second adhesive layer 96 that attaches the plurality of solar cells 94 to the polymer top sheet 98. In some embodiments, the second adhesive layer 96 is in contact with the top surface 93 of each of the plurality of solar cells 94. The second adhesive layer 96 can be any suitable adhesive. The prismatic silicone encapsulation layer can be bonded to the solar cells with a similar transparent silicone used to form the top sheet, such as Dow Corning DC 93-500. In some embodiments, the thickness of the second adhesive layer 92 is in a range of 8 microns to 15 microns. In some embodiments, the thickness of the second adhesive layer is in a range of 8 microns to 25 microns.

Although solar sheet 90 depicted in FIG. 20A and FIG. 20B does not include a bottom polymer layer, in some other embodiments, the solar sheet includes a bottom polymer layer 147, which may be described as a flexible backing layer or polymer bottom sheet, underlying the first adhesive layer. In such embodiments, the first adhesive layer does attach the bottom polymer layer to the other elements of the solar sheet, but is not configured to attach the solar sheet to an underlying surface of a space-based vehicle. In some embodiments, a bottom polymer layer includes polyvinyl fluoride (PVF) e.g., a TEDLAR® PVF film from DuPont.

In some embodiments not including textured coversheets, the solar sheet has a specific power of at least a specified value (e.g., at least 400 W/kg, at least 800 W/kg, at least 1000 W/kg, under AM1.5). In some embodiments, the solar sheet has a specific power falling with within a specified range (e.g., 400-2350 W/kg, 800-2350 W/kg, 1000-2350 W/kg, 1020-3000 W/kg, under AM1.5). The specific power of the solar sheets may additionally or alternatively be described in terms of AM0 (e.g., at least 510 W/kg, at least 1020 W/kg, at least 1270 W/kg or in a range of 10-3000 W/kg, 1020-3000 W/kg, 1270-3000 W/kg, 1020-4000 W/kg, under AM0).

As noted above, the areal mass of the solar sheet includes the encapsulating materials that form the solar sheet ready to be installed on a space-based vehicle. Decreasing the mass of solar sheet, increases the specific power of solar sheet. In some embodiments, the areal mass of the solar sheet may have a value that falls in a specified range (e.g., 70-280 g/m², 120-570 g/m², 120-300 g/m²). The areal power of a solar sheet is dependent on the efficiency of the solar cells as well as how tightly the solar cells are packed together in an array. In some embodiments, the areal power of the solar sheet may have a value that falls in a specific range (e.g., 260-330 W/m², 200-330 W/m² under AM1.5 or 325-450 W/m², 260-410 W/m² under AM0).

In some embodiments, each of the plurality of solar cells includes a backing layer 146. The backing layer can be formed of metal in some embodiments. In other embodiments, the backing layer can be formed of a polymer or a combination of metal and polymer. In some embodiments, the thickness of the metal backing layer is less than 30 μm, less than 15 μm, or less than 5 μm. In some embodiments, the metal backing layer has a thickness in a range of 2 to 30 microns. In some embodiments, the metal backing layer has a thickness in a range of 2 to 15 microns.

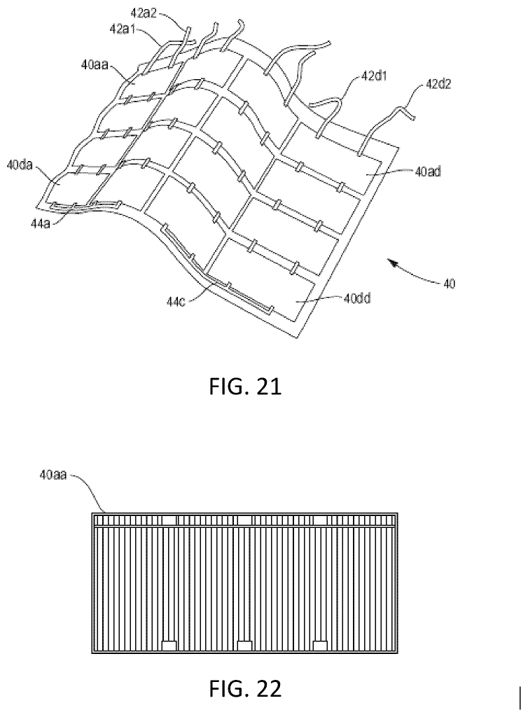

FIG. 21 illustrates the flexibility of a solar sheet 40, in accordance with an embodiment. FIG. 22 illustrates a plan view of a single solar cell 40aa. The flexible solar sheet may also include electrical components such as electrical interconnections between solar cells or electrical leads. As shown in FIG. 21, within a solar sheet 40 multiple solar cells may be electrically connected in columns and/or rows (e.g., cells 40aa-40da are connected in a solar cell string, cells 40ad-40dd are connected in a solar cell string). As also shown in FIG. 22, a solar sheet may include components for making electrical connections to the solar sheet (e.g., leads 42a1, 42a2 associated with one column, leads 42d1, 42d2 associated with another column and ground connections 44a and 44c).

Due to added mass of polymer materials in solar sheets, a solar sheet of a plurality of solar cells has a lower specific power than the specific power of the solar cells themselves. In addition, if the solar sheet has a top layer, the top layer may reduce the efficiency of the solar sheet (e.g., by absorbing or reflecting some of the incident light before it reaches the solar cell). Alternatively, the textured top sheet in accordance with some embodiments of the present disclosure can improve the efficiency of the solar sheet (e.g., by recapturing light that has reflected from the solar cell surface and redirecting this light back to the surface). In some embodiments, a solar cell has a specific power of at least a specified value (e.g., at least 800 W/kg, or at least 1000 W/kg, under AM1). Additionally or alternatively the threshold for specific power may be described in terms of AM0 light (e.g., at least 1020 W/kg, at least 1270 W/kg, under AM0). In some embodiments, a solar sheet has a specific power falling within a specified range (e.g., 800-2350 W/kg, 1000-2350 W/kg, 1000-3500 W/kg, under AM1.5). Additionally or alternatively, the range for specific power may be described in terms of AM0 light (e.g., 1020-3000 W/kg, 1270-3000 W/kg, 1020-4000 W/kg, under AM0).

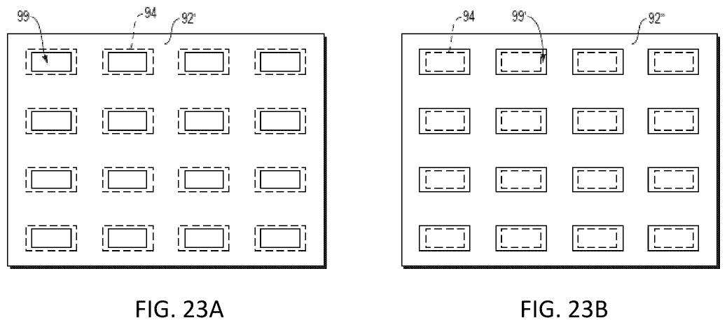

As noted above, in order to increase the specific power of a solar sheet, the areal mass of the solar sheet can be decreased. For example, in some embodiments, portions of first adhesive layer of the solar sheet include cutouts to reduce the mass of the solar sheet. FIG. 23A schematically illustrates a top view of a first adhesive layer 92′ that includes cutouts 99 with each cutout corresponding to a position of a solar cell 94. Although only the first adhesive layer is shown, for illustrative purposes the positions and areas of the corresponding solar cells in the solar sheet are indicated with dotted lines 94. In some embodiments, the area of each cutout 99 in the adhesive layer 92′ is smaller than the area of the corresponding solar cell 94, as illustrated in FIG. 23A. In some embodiments, the area of each cutout 99′ in an adhesive layer 92″ is larger than the area of the corresponding solar cell 94, as illustrated in FIG. 23B. In some embodiments, the area of each cutout in an adhesive layer is about the same as the area of the corresponding solar cell. In such embodiments, a frame or window structure for the first adhesive layer provides sufficient adhesion to secure the solar sheet to an underlying component of the space-based vehicle while achieving a significant mass reduction.

In some embodiments, the second adhesive layer includes a plurality of cutouts, each corresponding to a position of a solar cell in the solar sheet. In some embodiment, both the first adhesive layer and the second adhesive layer include a plurality of cutouts, each corresponding to a position of a solar cell in the solar sheet.

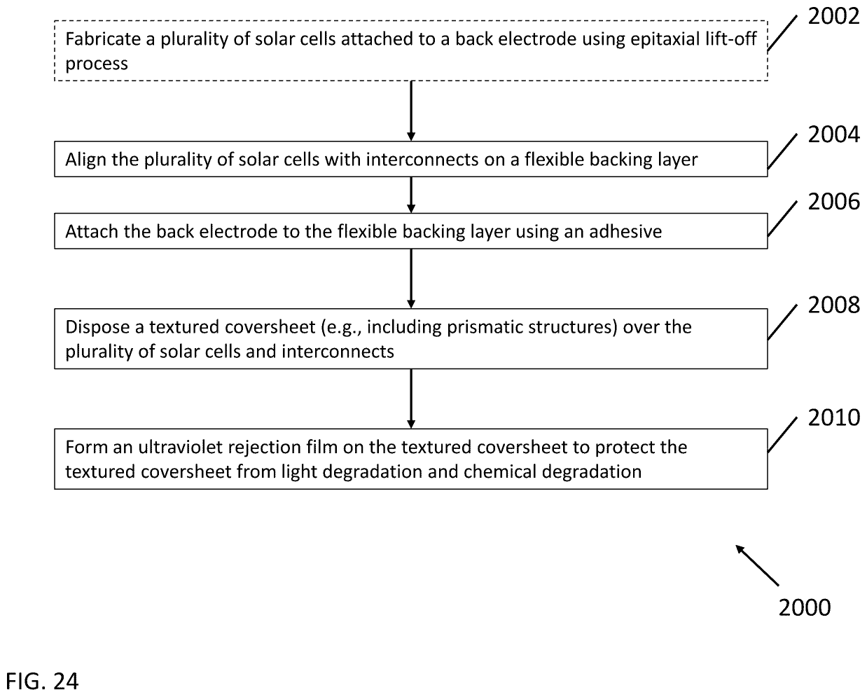

FIG. 24 illustrates a flow chart showing an example method 2000 for manufacturing a thin film solar sheet 100 for space applications as taught herein. Those skilled in the art will appreciate that the order in which the steps are presented in the example method 2000 are not limiting and merely meant to facilitate explanation of the subject matter taught herein, For example, in some embodiments, For example, step 2008 can be performed prior to step 2006. The method 2000 includes an optional step of fabricating a plurality of solar cells 130 attached to a back electrode 146 using an epitaxial lift-off process (step 2002). For example, the solar cells can be inverted metamorphic multi-junction solar cells as described earlier. The method 2000 includes aligning the plurality of solar cells 130 with interconnects 139 on a flexible backing layer 147 (step 2004). For example, separate portions of the back electrode 146 that are electrically connected to the cathode or anode of the solar cells 130 can be attached to respective interconnects to conduct electricity out of the solar sheet 100. The method 2000 includes attaching the back electrode 146 to the flexible backing layer 147 using an adhesive (step 2006). The method 2000 includes disposing the textured coversheet 110 including prismatic structures 112 over the plurality of solar cells 130 and the interconnects 139 to encapsulate the plurality of solar cells 130 (step 2008). The method includes forming an ultraviolet rejection film 135 on the textured coversheet 110 (step 2010). For example, the film 135 can be deposited using electron-beam or sputter deposition or grown using epitaxial growth methods. In some embodiments, the ultraviolet rejection film 135 can be a longpass optical filter with a cut-on wavelength in a range of 340 nanometers to 400 nanometers. For example, the longpass optical filter reduces transmission below the cut-on wavelength. The ultraviolet rejection film 135 can reduce transmission of light at wavelengths at or around 350 nanometers by 50%. For even shorter wavelengths the transmission of light drops to or almost to zero.

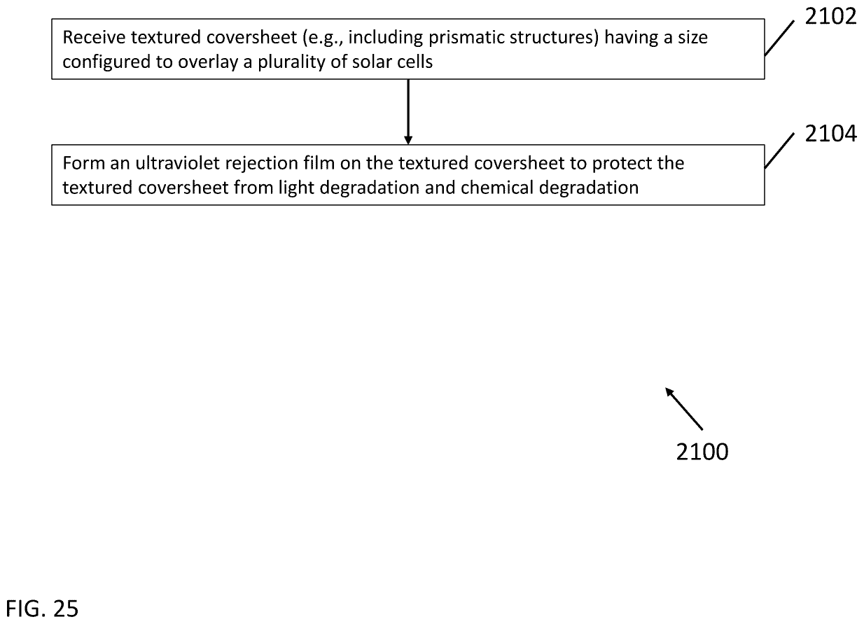

FIG. 25 illustrates a flow chart showing a method 2100 of manufacturing a coversheet for a plurality of solar cells for space applications as taught herein. The method 2100 includes receiving the textured coversheet 110 having a size configured to overlay the plurality of solar cells (step 2102). For example, the coversheet 110 can have an appropriate length and width to cover a planar array of the solar cells. The method 2100 includes forming the UVR film 135 on the textured coversheet 110 to protect the textured coversheet 110 from light degradation and chemical degradation (step 2104). For example, the film 135 can be deposited using electron-beam or sputter deposition or other deposition methods.

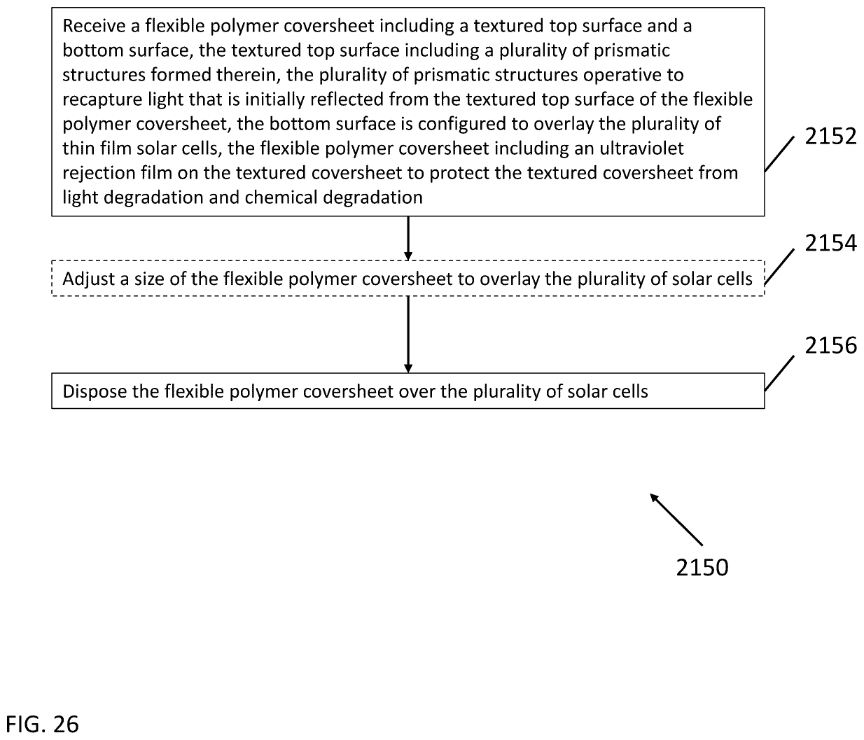

FIG. 26 illustrates a flow chart showing a method 2150 of protecting a plurality of solar cells configured for deployment in space as taught herein. The method 2150 includes receiving the flexible polymer coversheet 110 including the textured top surface 110a and the bottom surface 110b. The textured top surface includes the plurality of prismatic structures 112 formed therein, and the plurality of prismatic structures can recapture light that is initially reflected from the textured top surface of the flexible polymer coversheet. The bottom surface is configured to overlay the plurality of thin film solar cells. The flexible polymer coversheet also includes an ultraviolet rejection film on the textured coversheet to protect the textured coversheet from light degradation and chemical degradation. The method 2150 optionally includes adjusting a size of the flexible polymer coversheet to overlay the plurality of solar cells (step 2154). For example, the coversheet can be cut or melted using an implement or die to select a portion out of the sheet that is the appropriate size to overlie the plurality of solar cells. The method 2150 includes disposing the flexible polymer coversheet over the plurality of solar cells (step 2156). For example, the coversheet 110 can be adhered to a top surface of the plurality of solar cells or any layer or element (such as electrodes) that is overlying the solar cells. Disposing the coversheet over the plurality of solar cells can include encapsulating the solar cells and interconnects.

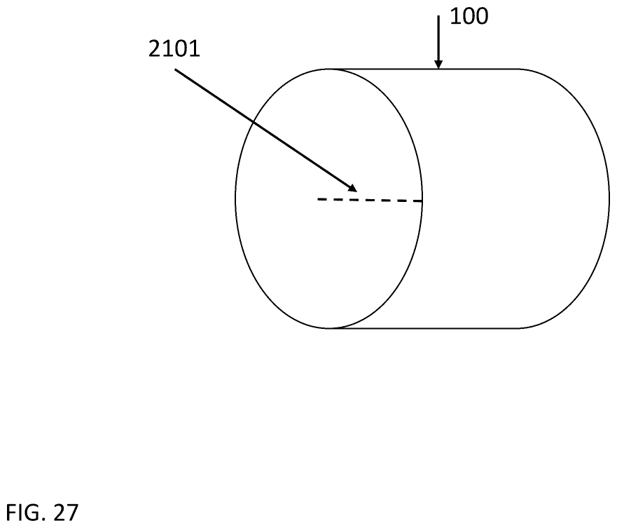

FIG. 27 illustrates a perspective view of the flexible solar sheet 100 in a state of being rolled up. As noted previously, the flexible solar sheet can be rolled or bent in some embodiments to enable storage or transport of the sheet before it is affixed to the space-based vehicle. The solar sheet 100 can also be rolled or bent for stowage aboard the space-based vehicle. The solar sheet 100 can remain stowed during launch and can be unfurled or deployed once the vehicles is in space. In some embodiments, a bend radius 2101 of the solar sheet 100 can be as small as 1 to 2 inches.

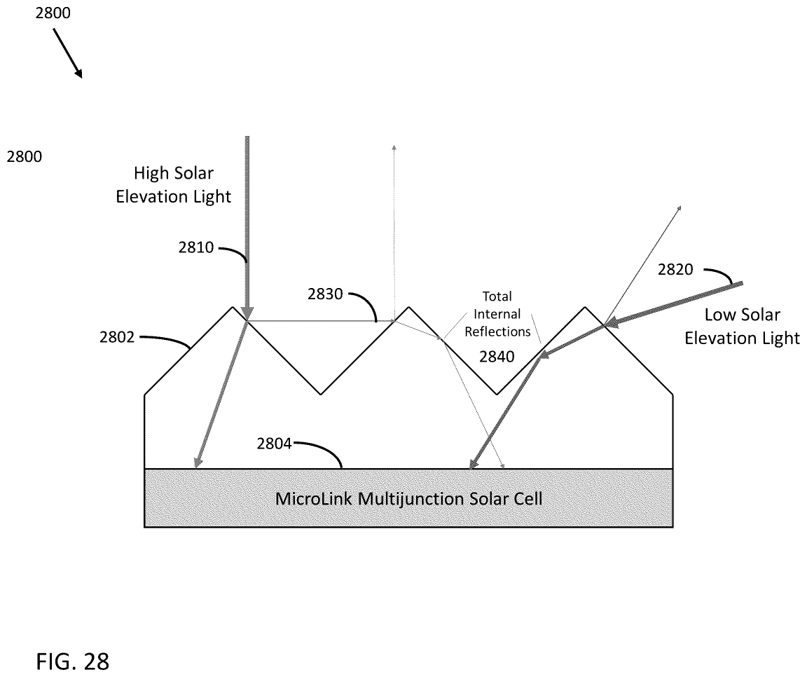

FIG. 28 is a Prismatic ray trace model 2800. The model shows light propagation from a solar source. Light that comes from a high solar elevation light 2810 strikes and is refracted and strikes a multi-junction solar cell 2804. Part of the solar strike 2810 is reflected as in 2830 then restrikes the prismatic structure 2802 and is refracted down toward the solar cell 2804. The reflection is shown in 2840. A low solar elevation light 2820 strikes the prismatic cover 2802 and is refracted down to strike the solar cell 2804. The prismatic surface 2802 provides improved optical transmission (reduced reflection) compared to planar surfaces. This is enabled by “recapturing” the first prism surface reflection that is transmitted onto an adjacent prism surface.

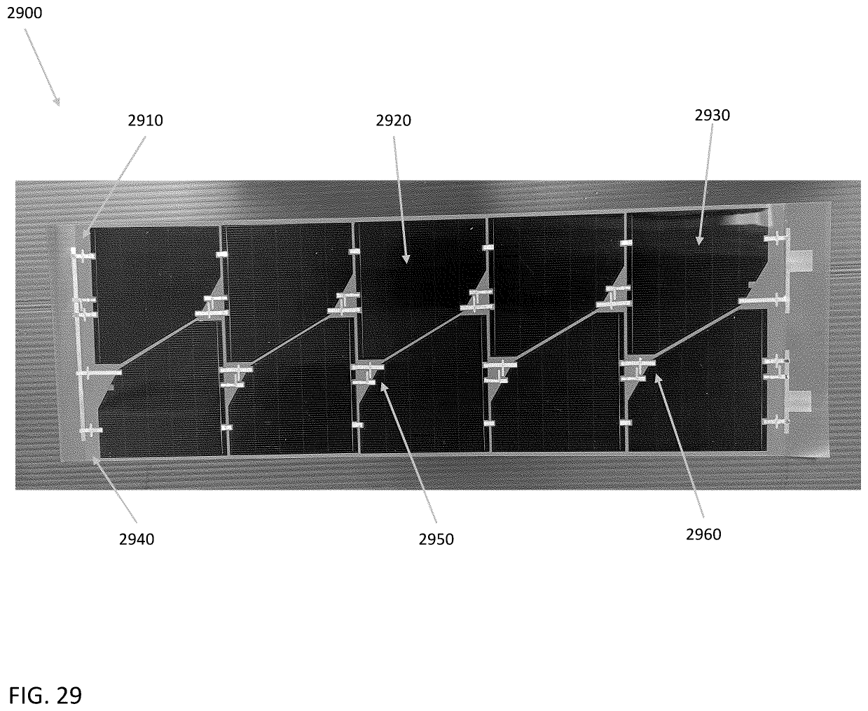

FIG. 29 is an assembly drawing of a textured solar power modules for satellite 2900. The module is mounted to Kapton tape 2910. The Kapton 2910 uses RTV bonding adhesive 2940. Mounted to the Kapton 2910 with RTV 2940 is a 37 cm2 Quartex cell 2920. The top silicone surface is coated with an oxide based, multi-layer dielectric ultraviolet rejection (UVR) film 2930 to reflect/absorb UV or low energy radiation (such as protons) that would darken the silicone and protect against atomic oxygen attack of the polymer in low earth orbit (LEO). There is an Ag-Kovar interconnect with in plane strain relief 2950. There is also a GaAs ELO bypass diode 2960.

While the present invention has been described with reference to illustrative embodiments thereof, those skilled in the art will appreciate that various changes in form in detail may be made without parting from the intended scope of the present invention as defined in the appended claims.

As may be recognized by those of ordinary skill in the pertinent art based on the teachings herein, numerous changes and modifications may be made to the above-described and other embodiments of the present disclosure without departing from the spirit of the invention as defined in the appended claims. Accordingly, this detailed description of embodiments is to be taken in an illustrative, as opposed to a limiting, sense. Those skilled in the art will recognize, or be able to ascertain using no more than routine experimentation, many equivalents to the specific embodiments of the taught herein. Such equivalents are intended to be encompassed by the following claims.

1. A solar sheet configured for space-based applications, comprising:
a plurality of thin film solar cells;
a flexible polymer coversheet overlaying a light receiving surface of the plurality of thin film solar cells, a bottom surface of the flexible polymer coversheet faces the plurality of thin film solar cells, a top surface of the flexible polymer coversheet having texturing operative to recapture light that is initially reflected from the top surface of the flexible polymer coversheet; and
an ultraviolet rejection film disposed over the flexible polymer coversheet to protect the solar sheet from light degradation and chemical degradation.

2. The solar sheet of claim 1, wherein the textured top surface includes a plurality of prismatic structures.

3. The solar sheet of claim 1, wherein the flexible polymer coversheet overlays and encapsulates interconnects between thin film solar cells in the plurality of thin film solar cells.

4. The solar sheet of claim 1, wherein the flexible polymer coversheet encapsulates the light receiving surface of the plurality of thin film solar cells.

5. The solar sheet of claim 1, wherein the ultraviolet rejection film is a longpass optical filter with a cut-on wavelength in a range of 340 nanometers to 400 nanometers.

6. The solar sheet of claim 5, wherein the ultraviolet rejection film longpass optical filter reduces transmission of light at wavelengths below 350 nanometers.

7. The solar sheet of claim 1, wherein the flexible polymer coversheet has a thickness in a range from 50 micrometers to 1000 micrometers.

8. The solar sheet of claim 1, wherein a height of each prismatic structure in the plurality of prismatic structures is in a range from 1 micrometers to 100 micrometers.

9. The solar sheet of claim 1, wherein the flexible polymer coversheet is formed of a fluoropolymer.

10. The solar sheet of claim 9, wherein the fluoropolymer comprises at least one from the group of fluorinated ethylene propylene (FEP), ethylene tetrafluoroethylene (ETFE), ethylene chlorotrifluoroethylene (ECTFE), tetrafluoroethylene, hexafluoropropylene and vinylidene fluoride (THV), and polychlorotrifluoroethylene (PCTFE).

11. The solar sheet of any one of claim 1, wherein the flexible polymer coversheet is formed of silicone or Polyethylene terephthalate (PET).

12. The solar sheet of claim 1, wherein the plurality of prismatic structures includes inverted prism structures or prism structures that project outward from the top surface.

13. The solar sheet of claim 12, wherein each prism structure is a linear or curvilinear prism.

14. The solar sheet of claim 12, wherein each prism structure is a corner cube prism.

15. The solar sheet of claim 12, wherein each prism structure is a pyramidal prism.

16. The solar sheet of claim 1, wherein the plurality of prismatic structures is configured to increase a conversion efficiency of the plurality of solar cells for light at a zenith angle between 0° and 20°.

17. The solar sheet of claim 1, wherein a sidewall angle of each prismatic structure is in a range from 15 to 75 degrees.

18. The solar sheet of claim 17, wherein the sidewall angle is in a range from 35 degrees to 55 degrees.

19. The solar sheet of claim 1, wherein a specific power of the solar coversheet is in a range from 300 W/kg to 1500 W/kg under AM0.

20. The solar sheet of any one of claim 1, wherein a characteristic dimension of each prismatic structure in the plurality of prismatic structures is greater than a wavelength of incident light.

21. The solar sheet of claim 1, wherein the flexible polymer coversheet can be flexed in two dimensions to a bend radius in a range of 1-2 inches.

22. The solar sheet of claim 1, wherein a transmissivity of the solar sheet for light at a wavelength in a range from 400 nm to 1500 nm is greater than 95%.

23. The solar sheet of claim 1, further comprising an adhesive connecting the plurality of solar cells to the flexible polymer coversheet.

24. The solar sheet of claim 22, wherein the adhesive is a silicone-based, pressure-sensitive adhesive layer.

25. The solar sheet of claim 1, wherein the solar sheet is configured for installation on a surface of a space-based vehicle or on a surface of a component of a space-based vehicle.

26. A method of manufacturing a thin film solar sheet for space applications, comprising:
aligning a plurality of solar cells with interconnects on a flexible backing layer;
attaching a back electrode connected to the plurality of solar cells to the flexible backing layer using an adhesive;
disposing a textured coversheet over the plurality of solar cells and the interconnects; and
forming an ultraviolet rejection film on the textured coversheet to protect the textured coversheet from light degradation and chemical degradation.

27. The method of claim 26, wherein depositing the ultraviolet rejection film includes using an electron-beam evaporation deposition technique.

28. The method of claim 26, wherein depositing the ultraviolet rejection film includes using a sputter deposition technique.

29. The method of any one of claim 26, wherein the textured coversheet includes a plurality of prismatic structures.

30. The method of claim 29, wherein the method further comprises forming the plurality of prismatic structures on a first side of the textured coversheet.

31. The method of claim 30, wherein forming the plurality of prismatic structures includes embossing the plurality of prismatic structures on the first side of the textured coversheet.

32. The method of claim 30, wherein forming the plurality of prismatic structures includes casting, forming, or molding the plurality of prismatic structures on the first side of the textured coversheet.

33. The method of claim 30, wherein forming the plurality of prismatic structures includes scribing or physically etching the plurality of prismatic structures into the first side of the textured coversheet.

34. The method of claim 30, wherein forming the plurality of prismatic structures includes chemically etching or roughening the first side of the textured coversheet to form the plurality of prismatic structures.

35. The method of claim 26, wherein disposing the textured coversheet over the plurality of solar cells and the interconnects includes encapsulating the plurality of solar cells and the interconnects with the textured coversheet.

36. A method of manufacturing a coversheet for a plurality of solar cells for space applications, comprising:
receiving a textured coversheet having a size configured to overlay the plurality of solar cells; and
forming an ultraviolet rejection film on the textured coversheet to protect the textured coversheet from light degradation and chemical degradation.

37. A method of protecting a plurality of solar cells configured for deployment in space, comprising:
receiving a flexible polymer coversheet including a textured top surface and a bottom surface, the textured top surface including a plurality of prismatic structures formed therein, the plurality of prismatic structures operative to recapture light that is initially reflected from the textured top surface of the flexible polymer coversheet, the bottom surface is configured to overlay the plurality of thin film solar cells, the flexible polymer coversheet including an ultraviolet rejection film on the textured coversheet to protect the textured coversheet from light degradation and chemical degradation; and
disposing the flexible polymer coversheet over the plurality of solar cells.

38. The method of claim 37, further comprising adjusting a size of the flexible polymer coversheet to overlay the plurality of solar cells.

39. A device to enhance light collection efficiency of a plurality of thin film solar cells, comprising:
a flexible polymer coversheet including a textured top surface and a bottom surface, the textured top surface including a plurality of prismatic structures formed therein, the plurality of prismatic structures operative to recapture light that is initially reflected from the textured top surface of the flexible polymer coversheet, the bottom surface is configured to overlay the plurality of thin film solar cells; and
an ultraviolet rejection film disposed over the flexible polymer coversheet to protect the plurality of thin film solar cells from light degradation and chemical degradation.

40. A space-based vehicle, comprising:
a solar sheet installed on a surface of the space-based vehicle or on a surface of a component of the space-based vehicle, the solar sheet including:
a plurality of thin film solar cells,
a flexible polymer coversheet overlaying a light receiving surface of the plurality of thin film solar cells, a bottom surface of the flexible polymer coversheet faces the plurality of thin film solar cells, a top surface of the flexible polymer coversheet having texturing operative to recapture light that is initially reflected from the top surface of the flexible polymer coversheet; and
an ultraviolet rejection film disposed over the flexible polymer coversheet to protect the solar sheet from light degradation and chemical degradation.

41. The space-based vehicle of claim 40, further comprising:
a power conditioning system configured to operate the plurality of thin film solar cells within a desired power range and configured to provide power in the form of a voltage compatible with an electrical system of the space-based vehicle.
